(19) United States
(12) Patent Application Publication
(10) Pub. No.: US 2026/0007019 A1
(43) Pub. Date: Jan. 1, 2026

(54) DISPLAY PANEL AND ELECTRONIC APPARATUS INCLUDING THE SAME

(71) Applicant: Samsung Display Co., Ltd., Yongin-Si (KR)

(72) Inventors: YOUNGMIN AHN, Yongin-si (KR); HANBUM KWON, Yongin-si (KR); EUNBYUL KIM, Yongin-si (KR)

(21) Appl. No.: 19/251,444

(22) Filed: Jun. 26, 2025

(30) Foreign Application Priority Data
Jun. 27, 2024 (KR) 10-2024-0084477

(51) Int. Cl. H10K 59/131

(52) U.S. Cl. CPC H10K 59/131

(57) ABSTRACT

Provided is a display panel including a pixel, a signal line electrically connected to the pixel, a plurality of signal pads connected to the signal line, and a plurality of alignment pads spaced apart from the plurality of signal pads in a first direction, wherein the plurality of signal pads each include a first conductive pattern electrically connected to an end portion of the signal line, a second conductive pattern disposed on the first conductive pattern, and a plurality of insulating patterns disposed between the first conductive pattern and the second conductive pattern, and the plurality of alignment pads and the plurality of insulating patterns include a same material.

### CROSS-REFERENCE TO RELATED APPLICATIONS

This U.S. non-provisional patent application claims priority, under 35 U.S.C. § 119, to Korean Patent Application No. 10-2024-0084477 filed on Jun. 27, 2024, the entire content of which is hereby incorporated by reference.

### BACKGROUND

The present disclosure herein relates to a display panel and an electronic apparatus including the same, and more particularly, to a display panel including a pad region and an electronic apparatus including the display panel.

Multimedia electronic apparatuses such as televisions, mobile phones, tablet PCs, navigation devices, and game consoles may include a display module which displays an image and senses an external input.

The display module may be bonded and electrically connected to a driving chip which provides an electrical signal required for displaying an image.

### SUMMARY

The present disclosure provides a display panel having a structure that enables inspection of a position of polymer patterns of a pad.

The present disclosure also provides an electronic apparatus that makes it possible to inspect whether polymer patterns of a pad and a bump of a data driver are aligned or not, thereby having improved bonding reliability between a display panel and a data driver.

An embodiment of the inventive concept provides a display panel including a pixel, a signal line electrically connected to the pixel, a plurality of signal pads connected to the signal line, and a plurality of alignment pads spaced apart from the plurality of signal pads in a first direction, wherein the plurality of signal pads each include a first conductive pattern electrically connected to an end portion of the signal line, a second conductive pattern disposed on the first conductive pattern, and a plurality of insulating patterns disposed between the first conductive pattern and the second conductive pattern, and the plurality of alignment pads and the plurality of insulating patterns include a same material.

In an embodiment, the plurality of insulating patterns may be spaced apart from one another and arranged in a second direction perpendicular to the first direction, and in a plan view, each of the plurality of insulating patterns may be enclosed by the second conductive pattern and the first conductive pattern.

A central point of at least one alignment pad among the plurality of alignment pads is at a same coordinate in the second direction as a central point of at least one insulating pattern among the plurality of insulating patterns.

A distance in the first direction between a central point of at least one alignment pad among the plurality of alignment pads and a central point of at least one insulting pattern among the plurality of insulating patterns may be an integer multiple of a distance in the first direction between central points of signal pads adjacent to each other among the plurality of signal pads.

The plurality of alignment pads and the plurality of insulating patterns may include a polymer.

The plurality of alignment pads and the plurality of insulating patterns may include a thermosetting polymer or a thermoplastic polymer.

In an embodiment, the plurality of alignment pads and the plurality of insulating patterns may include a colored polymer, a translucent polymer, or an opaque polymer.

In an embodiment, the plurality of alignment pads and the plurality of insulating patterns may be formed in a same process.

In an embodiment, in a plan view, each of the first conductive pattern and the second conductive pattern may be distanced from the plurality of alignment pads.

In an embodiment, in a plan view, the plurality of alignment pads may be disposed at an outer periphery of the plurality of signal pads.

In an embodiment, the display panel may further include a pad insulating layer disposed under the first conductive pattern, wherein the plurality of alignment pads may be disposed on the pad insulating layer.

In an embodiment, the display panel may further include at least one dummy pad disposed at an outer periphery of the plurality of signal pads in a plan view, wherein the dummy pad may include a different material from materials of the alignment pad and the insulating pattern, and the dummy pad may be formed in a different process from that for the alignment pad and the insulating pattern.

In an embodiment, the plurality of insulating patterns may include first to n-th insulating patterns arranged in a second direction perpendicular to the first direction, and central points of the respective first to n-th insulating patterns may have the same coordinate in the second direction as a central point of at least one alignment pad among the plurality of alignment pads. The integer “n” may be equal to or greater than 2.

In an embodiment, the plurality of alignment pads may include first to n-th alignment pads, and central points of the respective first to n-th alignment pads may have the same coordinate in the second direction as a central point of at least one insulating pattern among the plurality of insulating patterns.

In an embodiment of the inventive concept, an electronic apparatus includes a display panel including a plurality of signal pads and a plurality of alignment pads spaced apart from the plurality of signal pads in a first direction, an electronic component including a plurality of bump electrodes and electrically connected to the display panel through the plurality of bump electrodes, and an adhesive layer bonding the display panel and the electronic component, wherein the plurality of signal pads each include a first conductive pattern, a second conductive pattern disposed on the first conductive pattern, and a plurality of insulating patterns disposed between the first conductive pattern and the second conductive pattern, and the plurality of alignment pads and the plurality of insulating patterns include a same material.

In a plan view, at least one insulating pattern among the plurality of insulating patterns may overlap at least one bump electrode among the plurality of bump electrodes, and in a plan view, at least one alignment pad among the plurality of alignment pads may overlap at least one bump electrode among the plurality of bump electrodes.

In an embodiment, the plurality of insulating patterns may be spaced apart in a second direction perpendicular to the first direction, and in a plan view, each of the plurality of insulating patterns may be enclosed by the second conductive pattern and the first conductive pattern.

A central point of at least one alignment pad among the plurality of alignment pads may have the same coordinate in the second direction as a central point of at least one insulating pattern among the plurality of insulating patterns.

A distance in the first direction between a central point of at least one alignment pad among the plurality of alignment pads and a central point of at least one insulating pattern among the plurality of insulating patterns may be an integer multiple of a distance in the first direction between central points of bump electrodes adjacent to each other among the plurality of bump electrodes.

In an embodiment, the plurality of alignment pads and the plurality of insulating patterns may each include a polymer, and the plurality of alignment pads and the plurality of insulating patterns may be formed in a same process.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

FIG. 1 is an assembled perspective view of an electronic apparatus according to an embodiment of the inventive concept;

FIG. 2 is an exploded perspective view of an electronic apparatus according to an embodiment of the inventive concept;

FIG. 3 is a cross-sectional view of a display module according to an embodiment of the inventive concept;

FIG. 4 is a plan view of a display panel according to an embodiment of the inventive concept;

FIG. 5 is a plan view of an input sensing unit according to an embodiment of the inventive concept;

FIG. 6 is a cross-sectional view of a display module according to an embodiment of the inventive concept;

FIG. 7 is a perspective view of an electronic apparatus according to an embodiment of the inventive concept;

FIG. 8A is a plan view of some components of an electronic apparatus according to an embodiment of the inventive concept;

FIG. 8B is a plan view of some components of an electronic apparatus according to an embodiment of the inventive concept;

FIG. 8C is a cross-sectional view of a partial region of an electronic apparatus according to an embodiment of the inventive concept;

FIG. 8D is a cross-sectional view of a partial region of an electronic apparatus according to an embodiment of the inventive concept; and

FIGS. 9 to 13 are each a plan view of some components of an electronic apparatus according to another embodiment of the inventive concept.

### DETAILED DESCRIPTION

Embodiments of the inventive concept may be variously modified and have various forms, but specific embodiments will be illustrated in the drawings and described in detail in the description. However, this is not intended to limit the inventive concept to a specific disclosed form, and it should be understood that all changes, equivalents, and alternatives included in the spirit and scope of the inventive concept are included.

As used herein, the singular forms include the plural forms as well unless the context clearly indicates otherwise.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, or combinations thereof.

In this specification, it will be understood that when an element (or a region, a layer, a portion, or the like) is referred to as being “on”, “connected to” or “coupled to” another element, it may be directly disposed on, connected or coupled to the other element, or an intervening element may be disposed therebetween.

The terms such as “below”, “on lower side”, “above”, and “on upper side” may be used herein to describe the relationships of the elements illustrated in the drawings. These terms have relative concepts and are described on the basis of the directions indicated in the drawings.

As used herein, the wording “disposed on” may represent being disposed not only on an upper portion of any one member but also on a lower portion thereof.

As used herein, the wording “directly disposed” may mean that there is no layer, film, region, plate, etc. added between a portion such as a layer, film, region, or plate and another portion. For example, “directly disposed” may mean placing two layers or two members without using an additional member such as an adhesive member therebetween.

As used herein, the term “and/or” includes all of one or more combinations which may be defined by related elements.

Although the terms first, second, etc. may be used herein to describe various elements, these elements should not be limited to any order or priority by these terms. These terms are only used to distinguish one element from another element. For example, a first element may be referred to as a second element, and similarly, a second element may also be referred to as a first element without departing from the scope of the inventive concept.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Like reference numerals or symbols refer to like elements. Also, in the drawings, the thicknesses, ratios, and dimensions of the elements are exaggerated for effective description of the technical contents.

Hereinafter, a display panel and an electronic apparatus according to an embodiment of the inventive concept will be described with reference to the drawings.

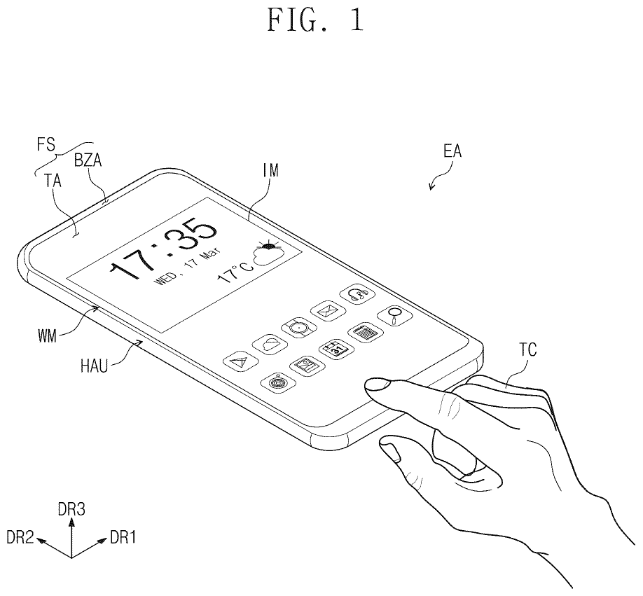

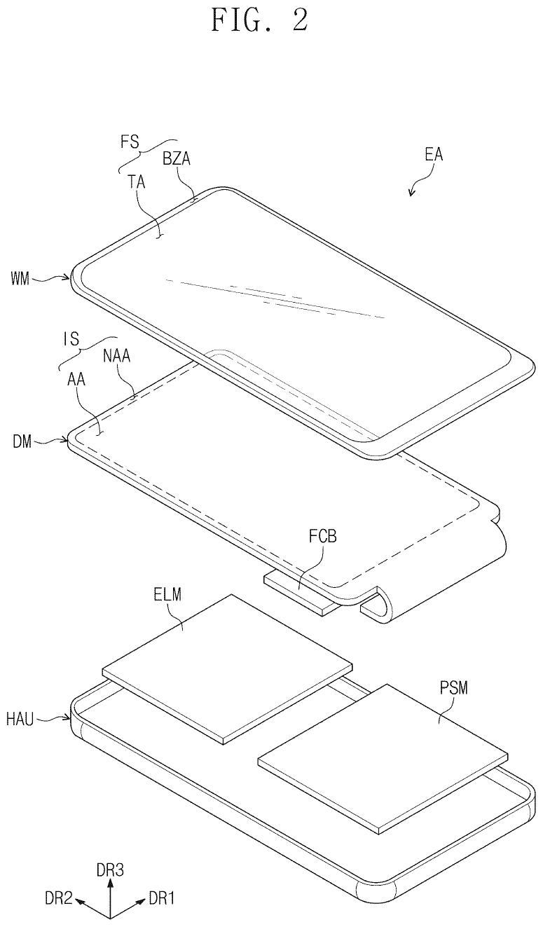

FIG. 1 is an assembled perspective view of an electronic apparatus EA according to an embodiment of the inventive concept. FIG. 2 is an exploded perspective view of the electronic apparatus EA according to an embodiment of the inventive concept.

Referring to FIGS. 1 and 2, the electronic apparatus EA may be activated in response to an electrical signal and may be an apparatus which displays an image IM and senses an external input TC. For example, the electronic apparatus EA may include an apparatus such as a monitor, a mobile phone, a tablet PC, a navigation device, and a game console. However, the embodiments of the electronic apparatus EA described above are examples, and thus the electronic apparatus EA is not limited to any one embodiment as long as the electronic apparatus EA does not depart from the inventive concept. In the present embodiment, the electronic apparatus EA is illustrated as a mobile phone.

The electronic apparatus EA may have a rectangular shape having short sides extending in a first direction DR1 and long sides extending in a second direction DR2 crossing the first direction DR1 in a plan view. However, an embodiment of the inventive concept is not limited thereto, and the electronic apparatus EA may have various shapes such as a circular shape and a polygonal shape in a plan view.

In the present embodiment, a third direction DR3 may be defined as a direction vertical to a plane defined by the first direction DR1 and the second direction DR2. A front surface (or an upper surface) and a rear surface (or a lower surface) of each of members constituting the electronic apparatus EA may be opposed to each other in the third direction DR3, and a normal direction of each of a front surface and a rear surface may be substantially parallel to the third direction DR3. A distance between a front surface and a rear surface defined along the third direction DR3 may correspond to a thickness of a member.

As used herein, the wording “in a plan view” may be defined as a state of being viewed in the third direction DR3. As used herein, the wording “in a cross-sectional view” may be defined as a state of being viewed in the first direction DR1 or the second direction DR2. The directions indicated by the first to third directions DR1, DR2, and DR3 are relative concepts and may be converted into other directions.

The electronic apparatus EA may be rigid or flexible. The term “flexible” may imply bendable characteristic, and the electronic apparatus EA may be an apparatus including any one from among a structure which is completely foldable to a structure which is bendable to a level of several nanometers. For example, the flexible electronic apparatus EA may include a curvable electronic apparatus, a rollable electronic apparatus, or a foldable electronic apparatus.

The electronic apparatus EA may display the image IM through a display surface FS parallel to each of the first direction DR1 and the second direction DR2. The image IM may include a static image as well as a dynamic image. FIG. 1 illustrates a clock and icons as an example of the image IM.

The display surface FS of the electronic apparatus EA may include only a flat surface, or may further include a curved surface which is bent from at least one side of the flat surface. The display surface FS may correspond to a front surface of the electronic apparatus EA and simultaneously correspond to a front surface of a window WM. Hereinafter, the display surface FS of the electronic apparatus EA and the front surface FS of the window WM will be denoted as the same reference numerals or symbols.

The electronic apparatus EA according to an embodiment may sense the external input TC applied from the outside. The external input TC may include inputs in various forms such as force, pressure, temperature, or light. In the present embodiment, the external input TC is illustrated as a user's hand applied to the front surface of the electronic apparatus EA. However, this is an example, and the external input TC may include detection of the presence of a pen or an input device, such as hovering or contact, applied close to the electronic apparatus EA.

The electronic apparatus EA may sense a user's input through the display surface FS which is defined on the front surface and respond to a sensed input signal. However, sensing of the external input TC is not limited to the front surface of the electronic apparatus EA and may be changed according to a design of the electronic apparatus EA. For example, the electronic apparatus EA may sense a user's input applied to a side surface or rear surface of the electronic apparatus EA.

The electronic apparatus EA may include the window WM, a display module DM, an electronic module ELM, a power module PSM, and a housing HAU. The window WM and the housing HAU may be coupled to each other to form an exterior of the electronic apparatus EA.

The window WM may be disposed on the display module DM. The window WM may cover a front surface IS of the display module DM and protect the display module DM from an external impact and scratch. The window WM may be coupled to the display module DM through an adhesive layer.

The window WM may include an optically transparent insulating material. For example, the window WM may include glass or a synthetic resin as a base film. The window WM may have a single-layered or multi-layered structure. For example, the window WM having a multi-layered structure may include synthetic resin films bonded with an adhesive, or a glass film and a synthetic resin film bonded with an adhesive. The window WM may further include a functional layer such as a hard coating layer, a phase control layer, and an anti-fingerprint layer disposed on a transparent base film.

The front surface FS of the window WM may correspond to the front surface FS of the electronic apparatus EA. The front surface FS of the window WM may include a transmission region TA and a bezel region BZA.

The transmission region TA may be an optically transparent region. The transmission region TA may transmit the image IM which is provided by the display module DM. In the present embodiment, the transmission region TA is illustrated as having a quadrangular shape, but the transmission region TA may have various shapes without being limited thereto.

The bezel region BZA may be a region having lower light transmittance than that of the transmission region TA. The bezel region BZA may be a region in which a material having a color is printed. The bezel region BZA may prevent transmission of light, thereby preventing a component of the display module DM disposed to overlap the bezel region BZA from being viewed from the outside.

The bezel region BZA may be adjacent to the transmission region TA. A shape of the transmission region TA may be substantially defined by the bezel region BZA. For example, the bezel region BZA may frame the transmission region TA and surround the transmission region TA. However, this is an example, and the bezel region BZA may be adjacent to only one side of the transmission region TA, or may be disposed on a side surface instead of the front surface in some embodiments. In addition, the bezel region BZA may be omitted.

The display module DM may be disposed between the window WM and the housing HAU. The display module DM may display the image IM and sense the external input TC. The image IM may be displayed on the front surface IS of the display module DM. The front surface IS of the display module DM may include an active region AA and a peripheral region NAA.

The active region AA may be activated in response to an electrical signal. For example, the active region AA may be a region in which the image IM is displayed and simultaneously may be a region in which the external input TC is sensed. The active region AA may overlap at least a portion of the transmission region TA. Accordingly, a user may view the image IM or provide the external input TC through the transmission region TA. However, this is an example, and a region in which the image IM is displayed and a region in which the external input TC is sensed in the active region AA may be separated from each other, and are not limited to any one embodiment.

The peripheral region NAA may be adjacent to the active region AA. For example, the peripheral region NAA may surround the active region AA. A driving circuit, a driving line, or the like for driving the active region AA may be disposed in the peripheral region NAA. The peripheral region NAA may overlap at least a portion of the bezel region BZA, and components disposed in the peripheral region NAA may be prevented from being viewed from the outside by the bezel region BZA.

The display module DM may include a display panel and an input sensing unit. The display panel may display the image IM, and the input sensing unit may sense the external input TC. Detailed description thereof will be made later.

A portion of the display module DM may be bent with respect to a bending axis extending in the first direction DR1. That is, the portion of the display module DM may be bent toward a rear surface of the display module DM corresponding to the active region AA. A flexible circuit board FCB may be connected to a portion of the display module DM that is bent, and accordingly, the flexible circuit board FCB may overlap the display module DM in a plan view.

The flexible circuit board FCB may be electrically connected to the display module DM on one side of the display module DM. The flexible circuit board FCB may generate an electrical signal that is provided to the display module DM or receive a signal that is generated from the display module DM and calculate a resultant value including information about a position at which the external input TC is sensed or intensity of the external input TC.

The electronic module ELM and the power module PSM may be disposed under the display module DM. The electronic module ELM and the power module PSM may be electrically connected through a separate circuit board.

The power module PSM may supply power required for an operation of the electronic apparatus EA. For example, the power module PSM may include a typical battery module.

The electronic module ELM may include various functional modules that operate the electronic apparatus EA. For example, the electronic module ELM may include a control module, a wireless communication module, an image input module, a sound input module, a sound output module, a memory, an optical module, an external interface module, and the like. The electronic module ELM may include a main circuit board, and the modules of the electronic module ELM may be mounted on the main circuit board or may be electrically connected to the main circuit board through a separate circuit board.

The control module of the electronic module ELM may control an overall operation of the electronic apparatus EA. For example, the control module may activate or deactivate the display module DM in accordance with a user's input. The control module may include at least one microprocessor. The optical module of the electronic module ELM may include a camera module, a proximity sensor, a biometric sensor that recognizes a part of a user's body (for example, a fingerprint, an iris, or a face), a lamp that outputs light, or the like.

The housing HAU may be coupled to the window WM to provide an internal space that accommodates the display module DM, the electronic module ELM, the power module PSM, and the flexible circuit board FCB. The housing HAU may include a material having relatively high rigidity. For example, the housing HAU may include a plurality of frames and/or plates including glass, plastic, or metal, or composed of a combination thereof. The housing HAU may protect components of the electronic apparatus EA accommodated in the housing HAU by absorbing an impact applied from the outside or preventing foreign substances/moisture infiltrating from the outside.

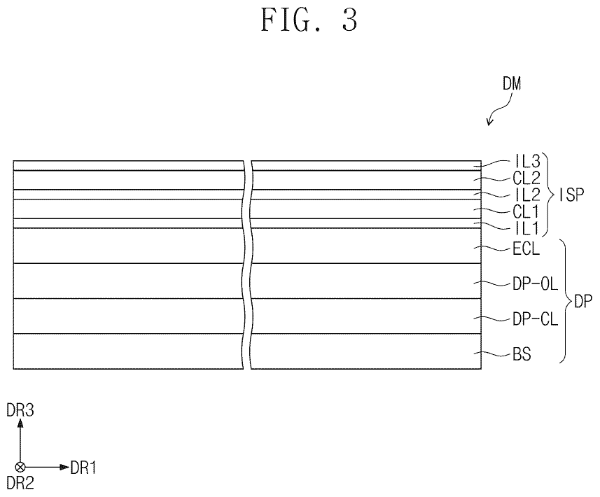

FIG. 3 is a cross-sectional view of a display module DM according to an embodiment of the inventive concept.

Referring to FIG. 3, the display module DM may include a display panel DP and an input sensing unit ISP. The input sensing unit ISP may be disposed on the display panel DP. For example, the input sensing unit ISP may be directly disposed on the display panel DP. In the present embodiment, the wording “the input sensing unit ISP is directly disposed on the display panel DP” means that the input sensing unit ISP is formed on the display panel DP through a continuous process and the input sensing unit ISP and the display panel DP are coupled to each other without a separate adhesive layer. That is, components of the input sensing unit ISP may be formed on a base surface which is provided by the display panel DP.

The display panel DP may display an image IM (see FIG. 1) in response to an electrical signal. The display panel DP according to an embodiment may be an emissive display panel, but is not particularly limited thereto. For example, the display panel DP may be an organic light-emitting display panel, an inorganic light-emitting display panel, or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include quantum dots, quantum rods, and the like. Hereinafter, the display panel DP will be described as an organic light-emitting display panel.

The display panel DP may include a base substrate BS, a circuit layer DP-CL, a display element layer DP-OL, and an encapsulation layer ECL which are sequentially stacked along a third direction DR3.

The base substrate BS may be a rigid substrate or a flexible substrate capable of being bent, folded, or rolled. For example, the base substrate BS may be a glass substrate, a metal substrate, a polymer substrate, or the like. The base substrate BS may provide a base surface on which the circuit layer DP-CL is disposed.

The base substrate BS may include an inorganic layer, an organic layer, or a composite material layer. The base substrate BS may have a single-layered or multi-layered structure. For example, the base substrate BS having a multi-layered structure may include synthetic resin layers and a multi-layered or single-layered inorganic layer disposed between the synthetic resin layers. A synthetic resin layer may include an acrylic resin, a methacrylic resin, a polyisoprene-based resin, a vinyl-based resin, an epoxy-based resin, a urethane-based resin, a cellulose-based resin, a siloxane-based resin, a polyamide-based resin, a perylene-based resin, or the like, but a material of the synthetic resin layer is not limited thereto.

The circuit layer DP-CL may be disposed on the base substrate BS. The circuit layer DP-CL may include at least one insulating layer, a semiconductor pattern, and a conductive pattern. The insulating layer, the semiconductor pattern, and the conductive pattern included in the circuit layer DP-CL may form driving elements such as a transistor, signal lines, and pads.

The display element layer DP-OL may be disposed on the circuit layer DP-CL. The display element layer DP-OL may include light-emitting elements which each emit light. For example, the light-emitting elements may include an organic light-emitting element, an inorganic light-emitting element, a micro-LED, a nano-LED, or the like. The light-emitting elements of the display element layer DP-OL may be electrically connected to driving elements of the circuit layer DP-CL and may emit light in response to an electrical signal which is provided by the driving elements.

The encapsulation layer ECL may be disposed on the display element layer DP-OL and encapsulate the light-emitting elements. The encapsulation layer ECL may include at least one thin film for improving optical efficiency of the display element layer DP-OL or protecting the display element layer DP-OL. For example, the encapsulation layer ECL may include at least one of an inorganic film or an organic film. The inorganic film of the encapsulation layer ECL may protect the light-emitting elements from moisture/oxygen. The organic film of the encapsulation layer ECL may protect the light-emitting elements from foreign substances such as dust particles.

The input sensing unit ISP may sense an external input TC (see FIG. 1) and provide an input signal including information about the external input TC so that the display panel DP may display an image IM according to the external input TC. The input sensing unit ISP may be driven using various methods such as a capacitive method, a resistive method, an infrared method, a sonic method, or a pressure method, and a driving method of the input sensing unit ISP is not limited to any one method as long as the input sensing unit ISP may sense an external input TC using the driving method. In the present embodiment, the input sensing unit ISP is described as an input sensing panel that is driven using a capacitive method.

The input sensing unit ISP may include a base layer IL1, a first sensing conductive layer CL1, a first sensing insulating layer IL2, a second sensing conductive layer CL2, and a second sensing insulating layer IL3 which are sequentially stacked along the third direction DR3. The base layer IL1 of the input sensing unit ISP may be in contact with the encapsulation layer ECL. However, an embodiment of the inventive concept is not limited thereto, and at least one of the base layer IL1 or the second sensing insulating layer IL3 may be omitted.

The first sensing conductive layer CL1 and the second sensing conductive layer CL2 may each have a single-layered or multi-layered structure. The conductive layer having a multi-layered structure may include at least two of transparent conductive layers and metal layers. The conductive layer having a multi-layered structure may include metal layers including different metal. The transparent conductive layer may include at least one of indium tin oxide (ITO), indium zinc oxide (IZO), zinc oxide (ZnO), indium tin zinc oxide (ITZO), PEDOT, metal nanowire, or graphene. The metal layer may include at least one of molybdenum, silver, titanium, copper, aluminum, or alloy thereof. For example, the first sensing conductive layer CL1 and the second sensing conductive layer CL2 may each have a double-layered structure, for example, a double-layered structure of ITO/copper, but are not limited thereto and may each have a triple-layered structure of titanium/aluminum/titanium.

The first sensing conductive layer CL1 and the second sensing conductive layer CL2 may each include sensing conductive patterns. The sensing conductive patterns of the first sensing conductive layer CL1 and the second sensing conductive layer CL2 may form sensing electrodes and sensing lines connected to the sensing electrodes constituting the input sensing unit ISP.

The base layer IL1, the first sensing insulating layer IL2, and the second sensing insulating layer IL3 may each include at least one of an inorganic film or an organic film. For example, the inorganic film may include at least any one of aluminum oxide, titanium oxide, silicon oxide, silicon oxynitride, zirconium oxide, or hafnium oxide, and the organic film may include at least any one of an acrylic resin, a methacrylic resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin. However, a material of the inorganic film and the organic film is not limited to the examples. In an embodiment, the base layer IL1 may include the inorganic film, and the first sensing insulating layer IL2 and the second sensing insulating layer IL3 may include the organic film, but an embodiment of the inventive concept is not limited thereto.

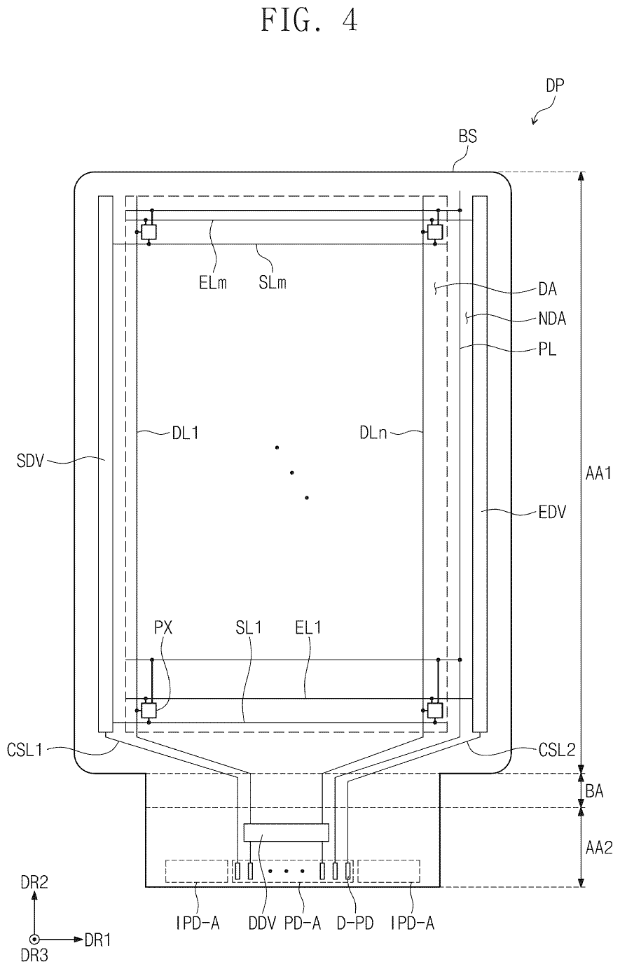

FIG. 4 is a plan view of a display panel DP according to an embodiment of the inventive concept.

Referring to FIG. 4, the display panel DP may include a base substrate BS, pixels PX, signal lines SL1 to SLm, DL1 to DLn, EL1 to ELm, CSL1, CSL2, and PL electrically connected to the pixels PX, a scan driver SDV, an emission driver EDV, a data driver DDV, and display pads D-PD.

The base substrate BS may provide a base surface on which electrical elements, lines, etc., of the display panel DP are disposed. The base substrate BS may include a first base region AA1, a bending region BA, and a second base region AA2 divided in a second direction DR2. The bending region BA may extend from the first base region AA1 in the second direction DR2. The second base region AA2 may extend from the bending region BA in the second direction DR2. Thus, the first base region AA1 and the second base region AA2 may be spaced apart with the bending region BA therebetween.

The first base region AA1 may include a display region DA. The display region DA may be a region in which light-emitting elements of the pixels PX are disposed. Accordingly, the pixels PX may display an image IM (see FIG. 1) through the display region DA. The display region DA may correspond to the active region AA (see FIG. 2) of the display module DM (see FIG. 2) and overlap the transmission region TA (see FIG. 2) of the window WM (see FIG. 2).

The first base region AA1 except the display region DA, the bending region BA, and the second base region AA2 may be defined as a non-display region NDA. The non-display region NDA may be a region which is adjacent to the display region DA and in which an image IM is not displayed. The non-display region NDA may surround the display region DA. The scan driver SDV, the emission driver EDV, and the data driver DDV for driving the pixels PX and the display pads D-PD electrically connected to the signal lines SL1 to SLm, DL1 to DLn, EL1 to ELm, CSL1, CSL2, and PL may be disposed in the non-display region NDA. The signal lines SL1 to SLm, DL1 to DLn, EL1 to ELm, CSL1, CSL2, and PL electrically connected to the pixels PX may extend and may be disposed in the non-display region NDA.

The bending region BA may be a region that is bent with respect to a bending axis extending in a first direction DR1. That is, the bending region BA may be bent toward a rear surface of the display panel DP corresponding to the first base region AA1. The second base region AA2 extending from one side of the bending region BA may overlap the first base region AA1 in a plan view according to bending of the bending region BA. That is, the second base region AA2 may be disposed on the rear surface of the display panel DP corresponding to the first base region AA1.

In the first direction DR1, a width of each of the bending region BA and the second base region AA2 may be smaller than a width of the first base region AA1. Since the bending region BA has a smaller width than the first base region AA1 in a direction parallel to the bending axis, the bending region BA may be easily bent. However, this is illustrated as an example, and in the first direction DR1, at least one of widths of the bending region BA and the second base region AA2 may be the same as a width of the first base region AA1, and an embodiment of the inventive concept is not limited thereto.

The second base region AA2 may be a region which is located below the first base region AA1 and provided flat due to bending of the bending region BA. The second base region AA2 may be a region in which the data driver DDV and signal lines, among the signal lines SL1 to SLm, DL1 to DLn, EL1 to ELm, CSL1, CSL2, and PL, extending toward the display pads D-PD via the bending region BA are disposed.

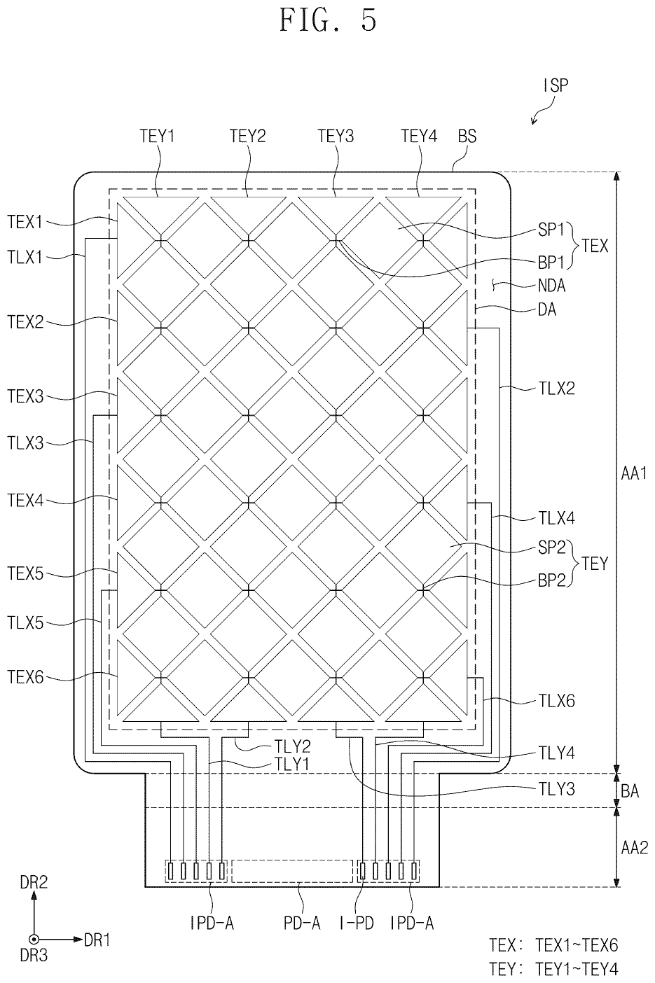

A region in which the display pads D-PD are disposed and a region in which sensing pads I-PD (see FIG. 5) are disposed may be referred to as a display pad region PD-A and a sensing pad region IPD-A, respectively. FIG. 4 illustrates that the display pad region PD-A and the sensing pad region IPD-A are divided in the first direction DR1. For example, the sensing pad region IPD-A may be provided to be adjacent to two sides of the second base region AA2 in the first direction DR1, and the display pad region PD-A may be provided at a center portion. However, an embodiment of the inventive concept is not necessarily limited thereto, and an arrangement position of the display pads D-PD and the sensing pads I-PD (see FIG. 5) may be variously changed.

The flexible circuit board FCB (see FIG. 2) may be disposed in the second base region AA2 in which the display pads D-PD and the sensing pads I-PD (see FIG. 5) are disposed and may be electrically connected to the display pads D-PD and the sensing pads I-PD (see FIG. 5). The flexible circuit board FCB (see FIG. 2) disposed adjacent to a lower end of the second base region AA2 may be located on the rear surface of the display panel DP according to bending of the bending region BA. Since the second base region AA2 and the flexible circuit board FCB (see FIG. 2) are located below the first base region AA1 on the front surface of the electronic apparatus EA (see FIG. 2), an area size of a bezel of the electronic apparatus EA (see FIG. 2) may be decreased.

The pixels PX may each include a pixel driving circuit including transistors (for example, a switching transistor, a driving transistor, etc.) and at least one capacitor and a light-emitting element electrically connected to the pixel driving circuit. The pixels PX may generate light in response to an electrical signal applied to each of the pixels PX and may display an image IM (see FIG. 1) through the display region DA. According to an embodiment, some of the pixels PX may include a transistor disposed in the non-display region NDA, but an embodiment of the inventive concept is not limited thereto.

The scan driver SDV and the emission driver EDV may be disposed in the non-display region NDA corresponding to the first base region AA1. The data driver DDV may be disposed in the non-display region NDA corresponding to the second base region AA2. In an embodiment, the data driver DDV may be provided in a form of an integrated circuit chip mounted in the non-display region NDA of the display panel DP. However, an embodiment of the inventive concept is not limited thereto, and the data driver DDV may be mounted on the flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, emission lines EL1 to ELm, first and second control lines CSL1 and CSL2, and a power line PL. Here, m and n indicate natural numbers.

The data lines DL1 to DLn may be insulated from and cross the scan lines SL1 to SLm and the emission lines EL1 to ELm. For example, the scan lines SL1 to SLm may extend in the first direction DR1 to be electrically connected to the scan driver SDV. The data lines DL1 to DLn may extend in the second direction DR2 to be electrically connected to the data driver DDV. The emission lines EL1 to ELm may extend in the first direction DR1 to be electrically connected to the emission driver EDV.

The power line PL may include a portion extending in the first direction DR1 and a portion extending in the second direction DR2. The portion extending in the first direction DR1 and the portion extending in the second direction DR2 of the power line PL may be disposed on different layers or may be integrally disposed at the same layer. The portion of the power line PL extending in the first direction DR1 may be electrically connected to the pixels PX and the portion of the power line PL extending in the second direction DR2. The portion, of the power line PL extending in the second direction DR2 may be disposed in the non-display region NDA and electrically connected to the display pads D-PD via the bending region BA and the second base region AA2 from the first base region AA1. The power line PL may provide a power voltage to the pixels PX.

The first control line CSL1 may be electrically connected to the scan driver SDV and extend toward the lower end of the second base region AA2 via the bending region BA. The second control line CSL2 may be electrically connected to the emission driver EDV and extend toward the lower end of the second base region AA2 via the bending region BA.

The display pads D-PD may be disposed adjacent to the lower end of the second base region AA2. The display pads D-PD may be disposed closer to a lower end of the base substrate BS than the data driver DDV in the second base region AA2. The display pads D-PD may be spaced apart along the first direction DR1. The power line PL, the first control line CSL1, and the second control line CSL2 may be each electrically connected to a corresponding display pad D-PD among the display pads D-PD. The data lines DL1 to DLn may be each electrically connected to a corresponding display pad D-PD among the display pads D-PD through the data driver DDV.

The display pads D-PD may be electrically connected to the flexible circuit board FCB (see FIG. 2) through an adhesive layer, and an electrical signal from the flexible circuit board FCB (see FIG. 2) may be transmitted to the display panel DP through the display pads D-PD. However, a method for connecting the display pads D-PD and the flexible circuit board FCB (see FIG. 2) is not limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may be provided with data voltages in response to scan signals. The pixels PX may emit light having luminance corresponding to the data voltages in response to emission signals, thereby generating an image IM (see FIG. 1). Emission time of the pixels PX may be controlled by the emission signals.

FIG. 5 is a plan view of an input sensing unit ISP according to an embodiment of the inventive concept. For convenience of description, FIG. 5 schematically illustrates components of the input sensing unit ISP disposed on the base substrate BS described above.

In an embodiment, the input sensing unit ISP may be driven using a mutual-cap type method. Referring to FIG. 5, the input sensing unit ISP may include first sensing electrodes TEX: TEX1 to TEX6, second sensing electrodes TEY: TEY1 to TEY4, first sensing lines TLX1 to TLX6, second sensing lines TLY1 to TLY4, and sensing pads I-PD. However, an embodiment of the inventive concept is not limited thereto, and the input sensing unit ISP may be driven using a self-cap type method.

The first sensing electrodes TEX may each extend along a first direction DR1 and may be arranged along a second direction DR2. FIG. 5 illustrates six first sensing electrodes TEX1 to TEX6. However, the number of first sensing electrodes TEX included in the input sensing unit ISP is not limited thereto. One first sensing electrode TEX may include first sensing patterns SP1 arranged along the first direction DR1 and first connection patterns BP1 connecting the first sensing patterns SP1.

The second sensing electrodes TEY may each extend along the second direction DR2 and may be arranged along the first direction DR1. FIG. 5 illustrates four second sensing electrodes TEY1 to TEY4. However, the number of second sensing electrodes TEY included in the input sensing unit ISP is not limited thereto. One second sensing electrode TEY may include second sensing patterns SP2 arranged along the second direction DR2 and second connection patterns BP2 connecting the second sensing patterns SP2.

The first sensing electrodes TEX and the second sensing electrodes TEY may be electrically insulated. The input sensing unit ISP may sense an external input TC (see FIG. 1) through a change in capacitance between the first sensing electrodes TEX and the second sensing electrodes TEY. The first sensing electrodes TEX and the second sensing electrodes TEY may be disposed in a region corresponding to the display region DA of the base substrate BS. Accordingly, the electronic apparatus EA (see FIG. 1) may display an image IM (see FIG. 1) and simultaneously sense an external input TC applied to the display region DA through the display region DA.

The first sensing lines TLX1 to TLX6 may be disposed in the non-display region NDA and respectively electrically connected to the first sensing electrodes TEX1 to TEX6. Some of the first sensing lines TLX1 to TLX6 may be disposed on a left side of the non-display region NDA, and the others of the first sensing lines TLX1 to TLX6 may be disposed on a right side of the non-display region NDA. For example, the first sensing lines TLX1, TLX3, and TLX5 connected to the first sensing electrodes TEX1, TEX3, and TEX5 disposed in odd-numbered rows may be respectively connected to left sides of the first sensing electrodes TEX1, TEX3, and TEX5, and the first sensing lines TLX2, TLX4, and TLX6 connected to the first sensing electrodes TEX2, TEX4, and TEX6 disposed in even-numbered rows may be respectively connected to right sides of the first sensing electrodes TEX2, TEX4, and TEX6. However, arrangement of the first sensing lines TLX1 to TLX6 is not limited thereto, and all the first sensing lines TLX1 to TLX6 may be disposed on the left side of the non-display region NDA or the right side of the non-display region NDA.

Each of the first sensing lines TLX1 to TLX6 may extend toward the second base region AA2 via the bending region BA from the first base region AA1. The first sensing lines TLX1 to TLX6 may be respectively electrically connected to the sensing pads I-PD disposed in the second base region AA2.

The second sensing lines TLY1 to TLY4 may be disposed in the non-display region NDA and respectively electrically connected to the second sensing electrodes TEY1 to TEY4. Some of the second sensing lines TLY1 to TLY4 may be disposed adjacent to the left side of the non-display region NDA, and the others of the second sensing lines TLY1 to TLY4 may be disposed adjacent to the right side of the non-display region NDA. For example, in the first direction DR1, the second sensing lines TLY1 and TLY2 electrically connected to the second sensing electrodes TEY1 and TEY2 disposed on a left side among the second sensing electrodes TEY1 to TEY4 may be disposed adjacent to a left side of the first base region AA1, and the second sensing lines TLY3 and TLY4 electrically connected to the second sensing electrodes TEY3 and TEY4 disposed on a right side among the second sensing electrodes TEY1 to TEY4 may be disposed adjacent to a right side of the first base region AA1. However, arrangement of the second sensing lines TLY1 to TLY4 is not limited thereto.

The second sensing lines TLY1 to TLY4 may each extend toward the second base region AA2 via the bending region BA from a region adjacent to a lower end of the first base region AA1. The second sensing lines TLY1 to TLY4 may be respectively electrically connected to the sensing pads I-PD disposed in the second base region AA2.

In the first direction DR1, some of the sensing pads I-PD may be disposed in a region adjacent to a left side of the second base region AA2, and the others of the sensing pads I-PD may be disposed in a region adjacent to a right side of the second base region AA2. For example, the sensing pads I-PD may be divided into two groups spaced apart with a display pad region PD-A therebetween. However, arrangement of the sensing pads I-PD is not limited thereto.

The sensing pads I-PD may be disposed at the same layer as the display pads D-PD (see FIG. 4). The sensing pads I-PD may be disposed on a different layer from the first and second sensing lines TLX1 to TLX6 and TLY1 to TLY4 and may be connected to the first and second sensing lines TLX1 to TLX6 and TLY1 to TLY4 through a contact hole. However, an embodiment of the inventive concept is not limited thereto, and the sensing pads I-PD may be disposed on a different layer from the display pads D-PD (see FIG. 4). For example, the sensing pads I-PD may be integrally formed with the first and second sensing lines TLX1 to TLX6 and TLY1 to TLY4 at the same layer.

The first and second sensing lines TLX1 to TLX6 and TLY1 to TLY4 may be disposed above components of the display panel DP (see FIG. 4) in a region corresponding to the non-display region NDA of the base substrate BS. Accordingly, the first and second sensing lines TLX1 to TLX6 and TLY1 to TLY4 may overlap the components of the display panel DP (see FIG. 4) in the bending region BA and the second base region AA2.

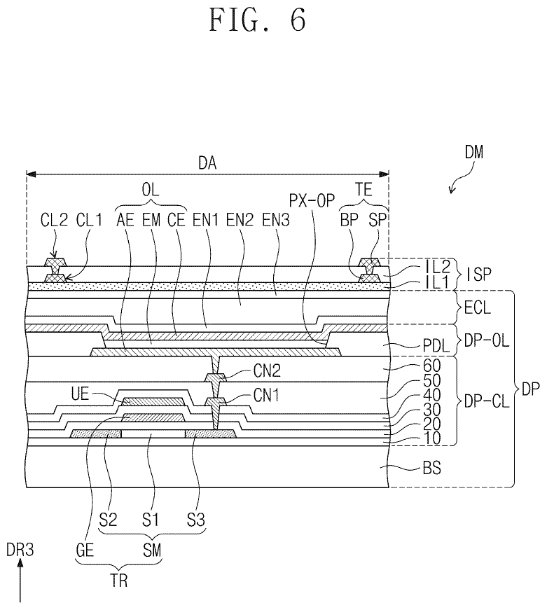

FIG. 6 is a cross-sectional view of a display module DM according to an embodiment of the inventive concept. FIG. 6 illustrates a cross section of the pixel PX (see FIG. 4) disposed in a display region DA.

Referring to FIG. 6, the display module DM may include a display panel DP and an input sensing unit ISP disposed on the display panel DP. The above descriptions may be equally applied to each of components.

As described with reference to FIG. 3, the display panel DP may include the base substrate BS, the circuit layer DP-CL, the display element layer DP-OL, and the encapsulation layer ECL.

The base substrate BS may have an insulating property and provide a base surface on which components of the display module DM are disposed. The base substrate BS may have flexibility so as to be bendable. As described above, the base substrate BS may include the first base region AA1 (see FIG. 4), the bending region BA (see FIG. 4), and the second base region AA2 (see FIG. 4), and the bending region BA (see FIG. 4) of the base substrate BS may be bent to a curvature.

The circuit layer DP-CL may include insulating layers 10 to 60 disposed on the base substrate BS, a transistor TR of the pixel PX (see FIG. 4), an upper electrode UE, and connection electrodes CN1 and CN2. The insulating layers 10 to 60 may include first to sixth insulating layers 10 to 60 which are sequentially stacked along a thickness direction on the base substrate BS. However, an embodiment of the insulating layers 10 to 60 included in the circuit layer DP-CL is not limited thereto and may be changed according to a configuration of or a manufacturing process for the circuit layer DP-CL.

The first insulating layer 10 may be disposed on the base substrate BS. The first insulating layer 10 may be provided as a buffer layer and/or a barrier layer that prevents foreign substances from being introduced from the outside. The first insulating layer 10 may improve bonding force between the base substrate BS and a conductive pattern and/or a semiconductor pattern SM of the circuit layer DP-CL. The first insulating layer 10 may include at least any one of a silicon oxide layer or a silicon nitride layer. In an embodiment, the first insulating layer 10 may include silicon oxide layers and silicon nitride layers which are alternately stacked.

The pixel PX (see FIG. 4) may be disposed on the base substrate BS. The pixel PX (see FIG. 4) may be disposed to correspond to the display region DA. The pixel PX (see FIG. 4) may include the transistor TR and a light-emitting element OL.

The transistor TR may include the semiconductor pattern SM and a gate electrode GE. The semiconductor pattern SM may be disposed on the first insulating layer 10. The semiconductor pattern SM may include a channel S1, a source S2, and a drain S3. The semiconductor pattern SM may include a silicon semiconductor, and may include a single crystal silicon semiconductor, a poly silicon semiconductor, or an amorphous silicon semiconductor. An embodiment of the inventive concept is not limited thereto, and the semiconductor pattern SM may include an oxide semiconductor. The semiconductor pattern SM according to an embodiment of the inventive concept may be formed of various materials as long as the materials have a semiconductor property and is not limited to any one embodiment.

The semiconductor pattern SM may include a plurality of regions having different electrical properties according to whether the regions are doped or not or whether metal oxide is reduced or not. For example, the semiconductor pattern SM may include a region having high conductivity due to doping or reduction of metal oxide, and the region having high conductivity may serve as an electrode of the transistor TR or a signal line. This may correspond to the source S2 and the drain S3 of the transistor TR. The semiconductor pattern SM may include a region having relatively low conductivity due to being undoped, and this may correspond to the channel S1 (or an active) of the transistor TR.

The second insulating layer 20 may be disposed on the first insulating layer 10 and cover the semiconductor pattern SM. The gate electrode GE may be disposed on the second insulating layer 20. The second insulating layer 20 may be 5 disposed between the gate electrode GE and the semiconductor pattern SM of the transistor TR. The gate electrode GE may overlap the channel S1 of the semiconductor pattern SM in a plan view. The gate electrode GE may function as a mask in a process of doping the semiconductor pattern SM. The gate electrode GE may include heat-resistant molybdenum (Mo), molybdenum-containing alloy, titanium (Ti), titanium-containing alloy, etc., but is not limited thereto.

A structure of the transistor TR illustrated in FIG. 6 is an example, and the source S2 or the drain S3 of the transistor TR may be electrodes which are independently formed from the semiconductor pattern SM. In this case, the source S2 and the drain S3 may be in contact with the semiconductor pattern SM or may be connected to the semiconductor pattern SM by penetrating an insulating layer. In addition, the gate electrode GE may be disposed under the semiconductor pattern SM. The transistor TR according to an embodiment of the inventive concept may be formed in various structures and is not limited to any one embodiment.

The second insulating layer 20 and the third to sixth insulating layers 30 to 60 to be described later may include at least one of an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin.

The third insulating layer 30 may be disposed on the second insulating layer 20 and cover the gate electrode GE. The upper electrode UE may be disposed on the third insulating layer 30. The upper electrode UE may overlap the gate electrode GE in a plan view, and the gate electrode GE and the upper electrode UE overlapping each other may form a capacitor.

The fourth insulating layer 40 may be disposed on the third insulating layer 30 and cover the upper electrode UE. The connection electrodes CN1 and CN2 may include a first connection electrode CN1 and a second connection electrode CN2. The first connection electrode CN1 may be disposed on the fourth insulating layer 40. The fifth insulating layer 50 may be disposed on the fourth insulating layer 40 and cover the first connection electrode CN1. The second connection electrode CN2 may be disposed on the fifth insulating layer 50. The sixth insulating layer 60 may be disposed on the fifth insulating layer 50 and cover the second connection electrode CN2. In an embodiment, at least one of the fifth insulating layer 50 or the sixth insulating layer 60 may include an organic layer, cover a step between components disposed below the at least one of the fifth insulating layer 50 or the sixth insulating layer 60, and provide a flat upper surface.

The first connection electrode CN1 may be electrically connected to the semiconductor pattern SM through a contact hole penetrating the second to fourth insulating layers 20 to 40. The second connection electrode CN2 may be electrically connected to the first connection electrode CN1 through a contact hole penetrating the fifth insulating layer 50.

The first connection electrode CN1 and the second connection electrode CN2 may each include a conductive material. The first connection electrode CN1 and the second connection electrode CN2 may each include gold, silver, copper, aluminum, platinum, molybdenum, titanium, alloy thereof, and the like. At least one of the first connection electrode CN1 or the second connection electrode CN2 may include conductive layers having a multi-layered structure. For example, at least one of the first connection electrode CN1 or the second connection electrode CN2 may have a triple-layered structure of titanium/aluminum/titanium. However, an embodiment of the inventive concept is not limited thereto.

According to an embodiment of the circuit layer DP-CL, at least one of the first connection electrode CN1 or the second connection electrode CN2 may be omitted. Alternatively, according to an embodiment of the circuit layer DP-CL, an additional connection electrode connecting the transistor TR and the light-emitting element OL may be further disposed. A method for electrically connecting the light-emitting element OL and the transistor TR may be variously changed according to the number of insulating layers disposed between the light-emitting element OL and the transistor TR and is not limited to any one embodiment.

The display element layer DP-OL may include the light-emitting element OL and a pixel-defining film PDL. The light-emitting element OL and the pixel-defining film PDL may be disposed on the sixth insulating layer 60. The light-emitting element OL may include a first electrode AE, an emission layer EM, and a second electrode CE.

The first electrode AE may be electrically connected to the second connection electrode CN2 through a contact hole penetrating the sixth insulating layer 60. The first electrode AE may be electrically connected to the transistor TR through the first and second connection electrodes CN1 and CN2.

A pixel opening PX-OP which exposes at least a portion of the first electrode AE may be defined in the pixel-defining film PDL. A region of the first electrode AE exposed from the pixel-defining film PDL may correspond to a light-emitting region. The pixel-defining film PDL may include an inorganic layer, an organic layer, or a composite material layer. According to an embodiment, the pixel-defining film PDL may further include a black pigment or black dye.

The emission layer EM may be disposed on the first electrode AE. The emission layer EM may provide color light. The emission layer EM may be disposed to correspond to the pixel opening PX-OP defined in the pixel-defining film PDL. The light-emitting element OL and the pixel opening PX-OP may be provided in plurality, and emission layers EM of the light-emitting elements OL may be disposed to respectively correspond to the pixel openings PX-OP and may be provided in a form of a pattern in which the emission layers EM are spaced apart from each other. However, an embodiment of the inventive concept is not limited thereto, and the emission layers EM of the light-emitting elements OL may be formed as an integrated common layer.

The second electrode CE may be disposed on the emission layer EM and the pixel-defining film PDL. The second electrode CE may be provided as a common electrode continuously disposed in the plurality of pixels PX (see FIG. 4).

The light-emitting element OL may further include at least one of a hole control region disposed between the first electrode AE and the emission layer EM or an electron control region disposed between the emission layer EM and the second electrode CE. The hole control region may include at least one of a hole generation layer, a hole transport layer, or an electron blocking layer, and the electron control region may include at least one of an electron generation layer, an electron transport layer, or a hole blocking layer.

The encapsulation layer ECL may be disposed on the display element layer DP-OL. The encapsulation layer ECL may be disposed on the light-emitting element OL and the pixel-defining film PDL and encapsulate the light-emitting element OL. The encapsulation layer ECL may include at least one of an inorganic film or an organic film. In the present embodiment, the encapsulation layer ECL may include a first inorganic film EN1, a second inorganic film EN3, and an organic film EN2 disposed between the first and second inorganic films EN1 and EN3. However, a configuration of the encapsulation layer ECL is not limited thereto as long as the encapsulation layer ECL may encapsulate the light-emitting element OL.

The first inorganic film EN1 may be disposed on the second electrode CE, and the organic film EN2 and the second inorganic film EN3 may be sequentially disposed on the first inorganic film EN1 in a thickness direction of the display panel DP. The first and second inorganic films EN1 and EN3 may protect the light-emitting element OL from moisture or oxygen introduced from the outside. For example, the first and second inorganic films EN1 and EN3 may each include at least one of silicon nitride, silicon oxynitride, silicon oxide, titanium oxide, or aluminum oxide. However, a material of the first and second inorganic films EN1 and EN3 is not limited to the example. The organic film EN2 may prevent foreign substances from being introduced into the light-emitting element OL and cover a step of components disposed below the organic film EN2. For example, the organic film EN2 may include an acrylic organic material. However, a material of the organic film EN2 is not limited to the example.

The input sensing unit ISP may be disposed on the display panel DP. The input sensing unit ISP may include a base layer IL1, a first sensing insulating layer IL2, a first sensing conductive layer CL1, and a second sensing conductive layer CL2. The input sensing unit ISP may further include the second sensing insulating layer IL3 (see FIG. 3) as illustrated in FIG. 3. The above descriptions may be equally applied to each of components.

The base layer IL1 may be in contact with an uppermost layer of the encapsulation layer ECL. For example, the base layer IL1 may be in contact with the second inorganic film EN3 of the encapsulation layer ECL. The base layer IL1 of the input sensing unit ISP may be directly formed on a base surface which is provided by the encapsulation layer ECL. However, an embodiment of the inventive concept is not limited thereto, and according to an embodiment, the base layer IL1 may be omitted, and in this case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulating layer IL2. The first sensing conductive layer CL1 and the second sensing conductive layer CL2 may constitute a sensing electrode TE. The sensing electrode TE may correspond to any one of the first and second sensing electrodes TEX and TEY (see FIG. 5) described above. For example, the first sensing conductive layer CL1 may include a connection pattern BP of the sensing electrode TE, and the second sensing conductive layer CL2 may include a sensing pattern SP of the sensing electrode TE. However, an embodiment of the inventive concept is not limited thereto. In some embodiments, the first sensing conductive layer CL1 may include the sensing pattern SP, and the second sensing conductive layer CL2 may include the connection pattern BP.

The connection pattern BP may correspond to the first connection pattern BP1 (see FIG. 5) or the second connection pattern BP2 (see FIG. 5) described above, and the sensing pattern SP may correspond to the first sensing pattern SP1 (see FIG. 5) or the second sensing pattern SP2 (see FIG. 5) described above. The connection pattern BP may be disposed on a different layer from the sensing pattern SP and may be connected to the sensing pattern SP through a contact hole penetrating the first sensing insulating layer IL2. However, an embodiment of the inventive concept is not limited thereto, and the connection pattern BP and the sensing pattern SP may be disposed at the same layer and integrally formed.

The sensing electrode TE may be a pattern having a mesh shape and disposed to correspond to a region in which the pixel-defining film PDL is disposed. However, an embodiment of the inventive concept is not limited thereto, and the sensing electrode TE may be provided as a pattern having a single shape overlapping the light-emitting element OL, and in this case, the sensing electrode TE may include a transparent conductive material.

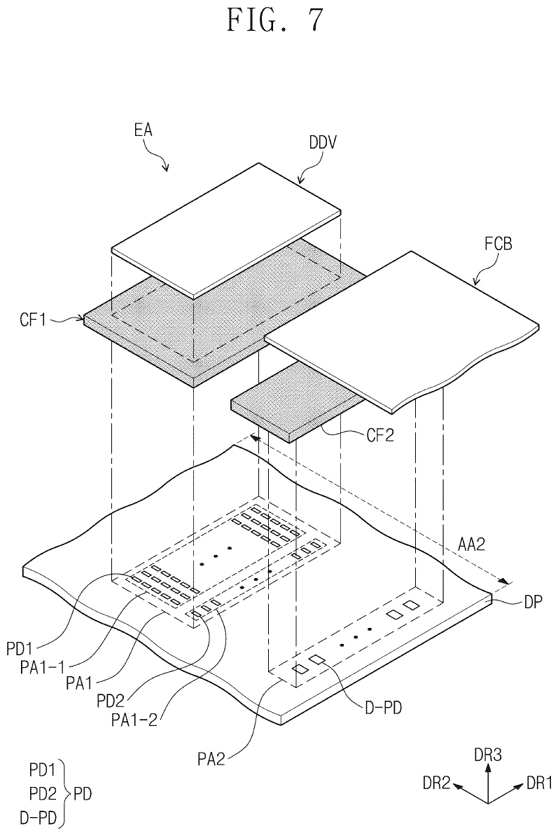

FIG. 7 is a perspective view of an electronic apparatus EA according to an embodiment of the inventive concept. FIG. 7 schematically illustrates some components of the electronic apparatus EA disposed to correspond to a second base region AA2.

The second base region AA2 corresponds to a partial region of the non-display region NDA (see FIG. 4). As illustrated in FIG. 7, among the non-display region NDA or the second base region AA2, a region to which a data driver DDV is bonded may be defined as a first pad region PA1, and a region to which a flexible circuit board FCB is bonded may be defined as a second pad region PA2.

The data driver DDV may be bonded to the first pad region PA1 through a first adhesive layer CF1, and the flexible circuit board FCB may be bonded to the second pad region PA2 through a second adhesive layer CF2. The first adhesive layer CF1 and the second adhesive layer CF2 may each include an adhesive synthetic resin. Each of the first adhesive layer CF1 and the second adhesive layer CF2 may be a non-conductive film (NCF). For example, each of the first adhesive layer CF1 and the second adhesive layer CF2 may be an adhesive resin not including conductive particles.

However, an embodiment of the inventive concept is not limited thereto, and in an embodiment, any one of the first adhesive layer CF1 and the second adhesive layer CF2 may be omitted. For example, the data driver DDV and the flexible circuit board FCB may be respectively bonded to the first pad region PA1 and the second pad region PA2 by ultrasonic bonding.

A display panel DP may include a plurality of pads PD. The plurality of pads PD may include first signal pads PD1, second signal pads PD2, and display pads D-PD. The first signal pads PD1, the second signal pads PD2, and the display pads D-PD may be pads disposed in a signal transmission path.

The first signal pads PD1 may be disposed to correspond to an output pad of the data driver DDV and may be input pads that receive a signal from the data driver DDV. The second signal pads PD2 may be disposed to correspond to an input pad of the data driver DDV and may be output pads which output a signal to the data driver DDV. The display pads D-PD may be panel input pads that receive a signal from the flexible circuit board FCB.

The first signal pads PD1 may be each electrically connected to the pixels PX (see FIG. 4) of the display panel DP through a signal line, and may transmit and receive a signal to and from the pixels PX (see FIG. 4). The second signal pads PD2 may be each electrically connected to a corresponding display pad D-PD among the display pads D-PD through a signal line, and the display pads D-PD and the second signal pads PD2 electrically connected to each other may transmit and receive a signal.

The first pad region PA1 may include a first sub pad region PA1-1 and a second sub pad region PA1-2. The first sub pad region PA1-1 may be defined as a region in which the first signal pads PD1 are disposed. The second sub pad region PA1-2 may be defined as a region in which the second signal pads PD2 are disposed.

The first signal pads PD1 may be arranged in a matrix configuration along a first direction DR1 and a second direction DR2 in the first sub pad region PA1-1. Among the first signal pads PD1, first signal pads PD1 arranged along the first direction DR1 may be defined as a pad row. FIG. 7 illustrates that five pad rows are arranged along the second direction DR2, but arrangement of the first signal pads PD1 is not limited thereto.

The second signal pads PD2 may be arranged along the first direction DR1 in the second sub pad region PA1-2. The second signal pads PD2 may be disposed as one pad row. However, arrangement of the second signal pads PD2 is not limited thereto.

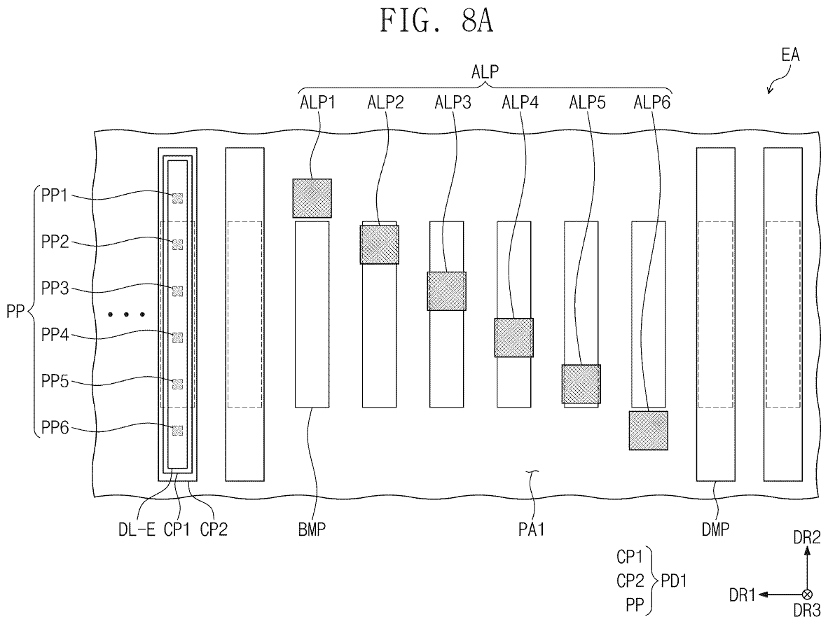

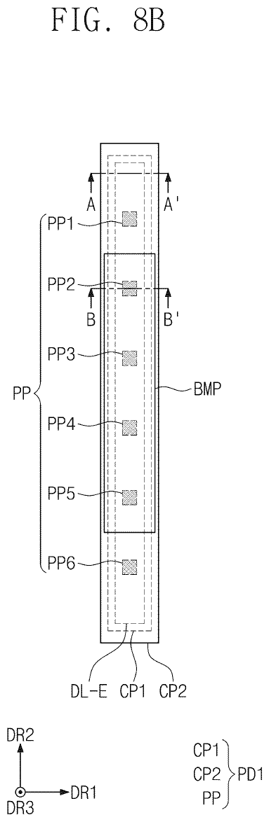

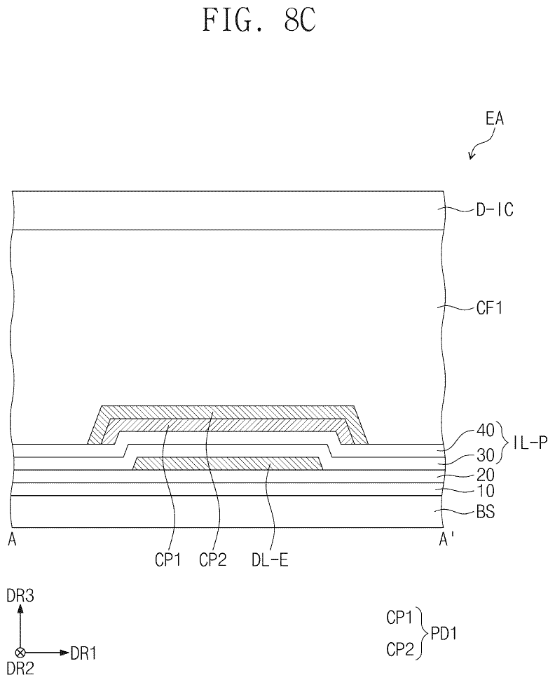

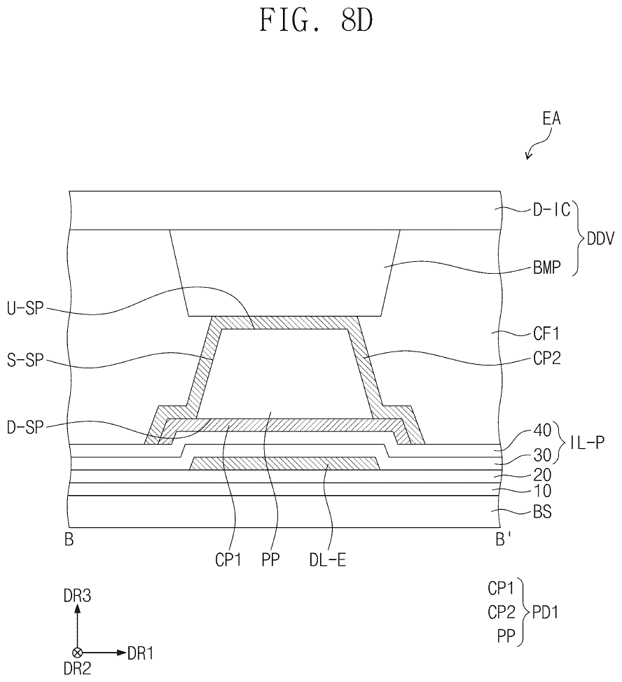

FIG. 8A is a plan view of some components of an electronic apparatus EA according to an embodiment of the inventive concept. FIG. 8B is a plan view of some components of an electronic apparatus EA according to an embodiment of the inventive concept. FIG. 8C is a cross-sectional view of a partial region of an electronic apparatus EA according to an embodiment of the inventive concept. FIG. 8D is a cross-sectional view of a partial region of an electronic apparatus EA according to an embodiment of the inventive concept.

FIG. 8A illustrates some components of the electronic apparatus EA corresponding to a first pad region PA1 in a plan view from a rear surface of the display panel DP (see FIG. 7) in a third direction DR3. FIG. 8B illustrates arrangement of an end portion DL-E of data lines DL1 to DLn (see FIG. 4), a first signal pad PD1, and a bump electrode BMP of a data driver DDV in a plan view. FIG. 8C illustrates a cross section taken along line A-A′ of FIG. 8B. FIG. 8D illustrates a cross section taken along line B-B′ of FIG. 8B.

FIGS. 8A to 8D illustrates the first signal pad PD1 of the first pad region PA1 and the data driver DDV. Hereinafter, description of the first pad region PA1 may be equally applied to the second pad region PA2 (see FIG. 7) except that the flexible circuit board FCB (see FIG. 7) is mounted instead of the data driver DDV. In addition, description of the first signal pad PD1 may be equally applied to the second signal pad PD2 and the display pad D-PD.

A plurality of first signal pads PD1 may be disposed in the first pad region PA1. For convenience, FIG. 8A illustrates only one first signal pad PD1. FIGS. 8A to 8D illustrate the data lines DL1 to DLn (see FIG. 4) including the end portion DL-E as an example of a signal line, but the signal line is not limited thereto. In addition, for convenience, only the end portion DL-E of the data lines DL1 to DLn (see FIG. 4) is illustrated. Hereinafter, the first pad region PA1 will be described focusing on the first sub pad region PA1-1 (see FIG. 7) in which the data lines DL1 to DLn (see FIG. 4) are disposed. Description of the first sub pad region PA1-1 may be equally applied to the second sub pad region PA1-2 (see FIG. 7) except that a connection signal line is disposed instead of the data lines DL1 to DLn (see FIG. 4).

Referring to FIGS. 8A to 8D, the first signal pad PD1 may include a first conductive pattern CP1, a second conductive pattern CP2, and an insulating pattern PP. Although not illustrated, the first conductive pattern CP1 may be connected to the end portion DL-E of the data lines DL1 to DLn (see FIG. 4) through at least one contact hole. FIG. 8A illustrates that one first signal pad PD1 includes six insulating patterns PP1 to PP6, but the number of insulating patterns PP is not limited thereto.

In a plan view, the end portion DL-E may have a shape extending in a second direction DR2. That is, a length or width of the end portion DL-E in a first direction DR1 may be less than a length or width of the end portion DL-E in the second direction DR2.

In a plan view, insulating patterns PP may overlap the first conductive pattern CP1 and the second conductive pattern CP2. In a plan view, the insulating patterns PP may be arranged along the second direction DR2. The insulating patterns PP may be disposed to be spaced apart from each other in the second direction DR2. In plan view, the insulating patterns PP are enclosed by the first conductive pattern CP1 and the second conductive pattern CP2.

FIG. 8A illustrates each of the insulating patterns PP as a square in a plan view, but this is not a limitation of the inventive concept. For example, a shape of the insulating patterns PP in a plan view may be changed into a rectangle, a polygon except a quadrangle, a circle, an ellipse, etc. In addition, shapes of the insulating patterns PP are not limited to being the same as each other.

Referring to FIGS. 8C and 8D, the end portion DL-E may be disposed on a second insulating layer 20. The end portion DL-E may be disposed at the same layer as the gate electrode GE illustrated in FIG. 6. The end portion DL-E may be formed through the same process as that for the gate electrode GE (see FIG. 6). The end portion DL-E may include the same material as the gate electrode GE (see FIG. 6).

However, a position of the end portion DL-E is not limited to being at the same layer as the gate electrode GE. For example, the end portion DL-E may be disposed at the same layer, include the same material, and have the same stacked structure as the upper electrode UE illustrated in FIG. 6. Alternatively, among a plurality of signal lines, some may be formed through the same process as that for the gate electrode GE (see FIG. 6), and others may be formed through the same process as that for the upper electrode UE (see FIG. 6).

The first conductive pattern CP1 may be disposed on a fourth insulating layer 40. The first conductive pattern CP1 may be connected to the end portion DL-E through a contact hole (not illustrated) that extends through the third and fourth insulating layers 30 and 40. Although not illustrated, in a plan view, the contact hole may overlap the end portion DL-E and the first conductive pattern CP1 and may not overlap the insulating pattern PP. For example, the contact hole may be disposed between the insulating patterns PP in a plan view. That is, the first conductive pattern CP1 may be in contact with the end portion DL-E through the contact hole. The second to fourth insulating layers 20, 30, and 40 may be formed through the same process as that for the second to fourth insulating layers 20, 30, and 40 of the display region DA illustrated in FIG. 6. In the present disclosure, insulating layers disposed between the end portion DL-E and the first conductive pattern CP1 may be defined as a pad insulating layer IL-P. In the present embodiment, the third and fourth insulating layers 30 and 40 may be defined as the pad insulating layer IL-P. A stacked structure of the pad insulating layer IL-P may be changed according to a stacked structure of the circuit layer DP-CL (see FIG. 6).

The first conductive pattern CP1 and the end portion DL-E may be distinguished by the pad insulating layer IL-P (for example, the third and fourth insulating layers 30 and 40) disposed therebetween.

The second conductive pattern CP2 may be disposed on the first conductive pattern CP1. A region of the second conductive pattern CP2 not overlapping the insulating pattern PP may be in contact with the first conductive pattern CP1. A region of the second conductive pattern CP2 overlapping the insulating pattern PP may be in contact with the insulating pattern PP.

In an embodiment, the first conductive pattern CP1 may be formed through the same process as that for the first connection electrode CN1 described with reference to FIG. 6, and the second conductive pattern CP2 may be formed through the same process as that for the second connection electrode CN2 described with reference to FIG. 6. The first conductive pattern CP1 may include the same material as the first connection electrode CN1 (see FIG. 6), and the second conductive pattern CP2 may include the same material as the second connection electrode CN2 (see FIG. 6). FIGS. 8C and 8D illustrates an embodiment in which the first conductive pattern CP1 is disposed on the fourth insulating layer 40. According to an embodiment, the first conductive pattern CP1 may be disposed on the third insulating layer 30, and in this case, the fourth insulating layer 40 may not be disposed in the pad region PA1 or PA2 (see FIG. 7). However, an embodiment of the inventive concept is not limited thereto, and a combination of connection electrodes which are formed through the same process as that for the first and second conductive patterns CP1 and CP2 may be variously selected according to a stacked structure of the circuit layer DP-CL (see FIG. 6) as long as the first and second conductive patterns CP1 and CP2 of different layers may be provided.

In a plan view, the second conductive pattern CP2 has a greater area size than the first conductive pattern CP1 and an edge of the second conductive pattern CP2 is disposed outside of an edge of the first conductive pattern CP1 and covers the edge of the first conductive pattern CP1. However, the inventive concept is not limited thereto. For example, the second conductive pattern CP2 may have substantially the same area size as the first conductive pattern CP1, and an edge of the second conductive pattern CP2 may be substantially aligned with an edge of the first conductive pattern CP1.

A portion of the second conductive pattern CP2 may include a portion overlapping the insulating pattern PP in a plan view. The insulating pattern PP may be disposed between the first conductive pattern CP1 and the second conductive pattern CP2 in a cross-sectional view. The insulating pattern PP may be disposed on the first conductive pattern CP1 and covered with the second conductive pattern CP2. The second conductive pattern CP2 may cover an upper surface of the insulating pattern PP. The insulating pattern PP may be disposed on an inner side of the second conductive pattern CP2 and the first conductive pattern CP1 in a plan view.

In an embodiment, the second conductive pattern CP2 may have a multi-layered structure. For example, the second conductive pattern CP2 may have a triple-layered structure in which a first layer, a second layer, and a third layer are sequentially stacked. The second layer may have higher conductivity than the first layer and the third layer. For example, the first layer and the third layer may include titanium (Ti), and the second layer may include aluminum (Al).

The insulating pattern PP may be disposed in plurality. FIG. 8A illustrates six insulating patterns PP1 to PP6, but the number of insulating patterns PP is not limited thereto. The insulating pattern PP may include a polymer. The insulating pattern PP may include a thermosetting polymer. However, an embodiment of the inventive concept is not limited thereto, and the insulating pattern PP may include a thermoplastic polymer.

Referring to FIG. 8D, the data driver DDV may include a substrate D-IC and the bump electrode BMP, and the bump electrode BMP may be in contact with the first signal pad PD1.

The bump electrode BMP of the data driver DDV may extend through a first adhesive layer CF1 to be in contact with the second conductive pattern CP2 of the first signal pad PD1 through a bonding process. The electronic apparatus EA of the inventive concept may not include a conductive ball that is part of some products and is known to cause short circuit. A short circuit may not be caused by a conductive ball and energization failure if a conductive ball is not disposed between the first signal pad PD1 and the bump electrode BMP. The embodiments disclosed herein do not include the conductive ball, and there is low risk of short circuit even if the first signal pads PD1 are densely arranged. This reduced risk of short circuit is advantageous in providing a high-resolution panel.

Referring to FIG. 8A, the display panel DP (see FIG. 7) may include an alignment pad ALP disposed in the first pad region PA1. The alignment pad ALP may be an alignment mark or an identification mark for identifying alignment of the bump electrode BMP of the data driver DDV and the insulating pattern PP of the first signal pad PD1 to secure bonding reliability in a process of bonding the data driver DDV to the first pad region PA1 of the display panel DP (see FIG. 7).

The alignment pad ALP may be disposed at an outer periphery of the first pad region PA1 in the first direction DR1. Alignment pads ALP may be disposed on two sides of the first pad region PA1 with the plurality of first signal pads PD1 (see FIG. 7) therebetween. The alignment pad ALP may be disposed to be spaced apart from the plurality of first signal pads PD1 in the first direction DR1.

The alignment pad ALP may be disposed on a base substrate BS of the first pad region PA1, or may be disposed on one or more insulating layers 10, 20, 30, and 40. The conductive patterns CP1 and CP2 may not be disposed in a region in which the alignment pad ALP is disposed.

The alignment pad ALP may include the same material as the insulating pattern PP of the first signal pad PD1. The alignment pad ALP may include a polymer material. The alignment pad ALP may include a thermosetting polymer. Alternatively, the alignment pad ALP may include a thermoplastic polymer. The alignment pad ALP may include a colored or translucent/opaque polymer. Thus, after a bonding process, the alignment pad ALP may be recognized on the rear surface of the display panel DP (see FIG. 7). The alignment pad ALP may be formed in the same process as that for the first signal pad PD1. Thus, the insulating pattern PP and the alignment pad ALP may be arranged according to arrangement relationship in a pattern design in a plan view. That is, a position of the insulating pattern PP may be precisely derived from a position of the alignment pad ALP in a plan view.

Specifically, a center of at least one insulating pattern PP of the first signal pad PD1 in the second direction DR2 and a center of at least one alignment pad ALP may be positioned at the same coordinate along the second direction DR2 (i.e., the same distance from the reference point in the second direction DR2, or have a same coordinate in the second direction DR2). A center in the second direction DR2 may mean a position of a center of the insulating pattern PP or the alignment pad ALP in the second direction DR2 in a plan view (that is, in a third direction DR3). In other words, a center in the second direction DR2 may mean a central point of a component extending in the second direction DR2 when viewed in the first direction DR1.

For example, as illustrated in FIG. 8A, a center of a first insulating pattern PP1 may have the same coordinate in the second direction DR2 as a center of a first alignment pad ALP1. A center of a second insulating pattern PP2 may have the same coordinate in the second direction DR2 as a center of a second alignment pad ALP2. A center of a third insulating pattern PP3 may have the same coordinate in the second direction DR2 as a center of a third alignment pad ALP3. A center of a fourth insulating pattern PP4 may have the same coordinate in the second direction DR2 as a center of a fourth alignment pad ALP4. A center of a fifth insulating pattern PP5 may have the same coordinate in the second direction DR2 as a center of a fifth alignment pad ALP5. A center of a sixth insulating pattern PP6 may have the same coordinate in the second direction DR2 as a center of a sixth alignment pad ALP6. A and B “having the same coordinate in the second direction DR2,” as used herein, means A and B are the same distance away from the first direction DR1 in the second direction DR2.

The data driver DDV and the first signal pad PD1 may be electrically connected through a contact between the bump electrode BMP and the second conductive pattern CP2. Thus, it may be important for a portion of the first signal pad PD1 in which the insulating pattern PP is disposed and which protrudes toward the data driver DDV and a portion of the data driver DDV in which the bump electrode BMP is disposed to overlap in a plan view. That is, the number of insulating patterns PP of the first signal pad PD1 overlapping the bump electrode BMP of the data driver DDV may determine bonding reliability.

When viewed from the rear surface of the display panel DP (see FIG. 7), it may not be possible to directly recognize how many insulating patterns PP of the first signal pad PD1 the bump electrode BMP overlaps.

In the embodiments of the disclosure, the alignment pads ALP that have centers that have the same coordinate in the second direction DR2 as the insulating patterns PP of the first signal pad PD1 are disposed on two sides of the plurality of first signal pads PD1. Hence, positions of the centers of the insulating patterns PP may be determined based on the positions of the centers of the alignment pads ALP in the second direction DR2. The positions of the centers of the insulating patterns PP may be determined with enough precision to allow a calculation of how many insulating patterns PP one bump electrode BMP overlaps and is bonded to.

A position of the insulating pattern PP may not be visible from the rear surface of the display panel DP (see FIG. 7). However, a position of the alignment pad ALP may be visible from the rear surface of the display panel DP. Since the center of the first alignment pad ALP1 is patterned to be at the same coordinate in the second direction DR2 as the center of the first insulating pattern PP1, the center of the first insulating pattern PP1 in the second direction DR2 may be determined from the center of the first alignment pad ALP1. If the center of the first alignment pad ALP1 does not overlap the bump electrode BMP (i.e., the coordinate for the center of the first alignment pad ALP1 in the second direction DR2 does not fall within the range of coordinates in the second direction DR2 covered by the bump electrode BMP), the center of the first insulating pattern PP1 in the second direction DR2 will also not have a coordinate value in the second direction DR2 that overlaps the range covered by the bump electrode BMP. Similarly, based on a position of the sixth alignment pad ALP6, the sixth insulating pattern PP6 will not overlap the bump electrode BMP. In addition, seeing that the center of each of the second to fifth alignment pads ALP2, ALP3, ALP4, and ALP5 in the second direction DR2 overlaps the bump electrode BMP, the center of each of the second to fifth insulating patterns PP2, PP3, PP4, and PP5 in the second direction DR2 will overlap the coordinates in the second direction DR2 covered by the bump electrode BMP. As a result, the bump electrode BMP may be positioned to overlap and bond to four insulating patterns PP2 to PP5 of the six insulating patterns PP1 to PP6.

The alignment pads ALP may be disposed to be spaced apart at constant intervals in the first direction DR1. An interval between centers of at least two adjacent alignment pads ALP in the first direction DR1 may be the same as an interval between centers of insulating patterns PP in the first direction DR1 respectively included in adjacent first signal pads PD1. A center in the first direction DR1 may mean a central point of a component extending in the first direction DR1 when viewed in the second direction DR2.

Specifically, in FIG. 8A, all intervals between centers of adjacent alignment pads ALP in the first direction DR1 among the first to sixth alignment pads ALP1 to ALP6 may be the same as an interval between centers of insulating patterns PP in the first direction DR1 respectively included in adjacent first signal pads PD1.

The display panel DP (see FIG. 7) may further include a dummy pad DMP disposed in the first pad region PA1. FIG. 8A illustrates three dummy pads DMP spaced apart from the first signal pad PD1 in the first direction DR1, but the dummy pad DMP may be omitted, or one, two, or at least four dummy pads DMP may be disposed.

Each of the dummy pads DMP may be an electrically isolated pad. The dummy pads DMP may be disposed at an outermost periphery of the first pad region PA1 in the first direction DR1. In addition, the dummy pads DMP may be disposed between the first signal pad PD1 and the alignment pad ALP.

The dummy pads DMP may include a different material from a material of the alignment pads ALP. The dummy pads DMP may be formed in a different process from that for the alignment pads ALP. The dummy pads DMP may include the same material as the first conductive pattern CP1 and/or the second conductive pattern CP2. The dummy pads DMP may be formed in the same process as that for the first conductive pattern CP1 and/or the second conductive pattern CP2.

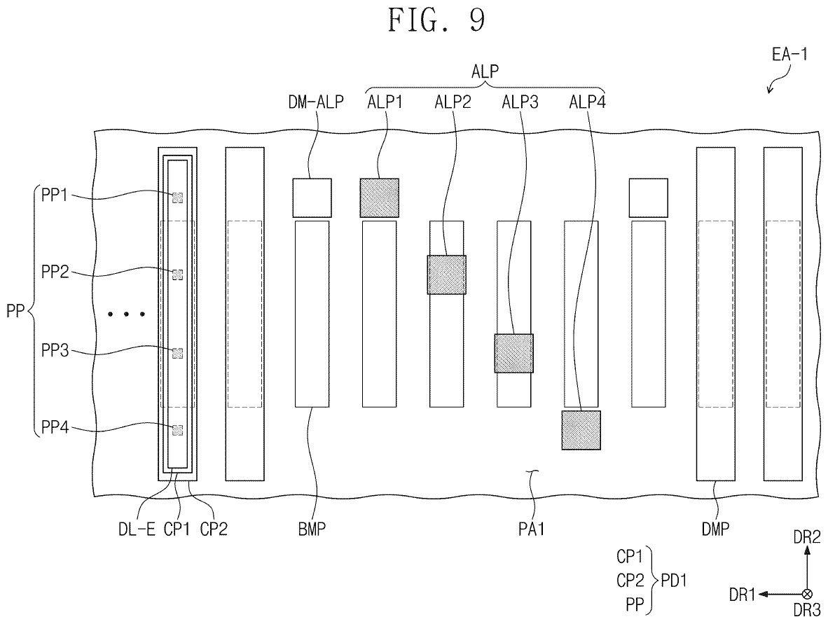

Each of FIGS. 9 to 13 is a plan view of some components of electronic apparatuses EA-1, EA-2, EA-3, EA-4, and EA-5 according to another embodiment of the inventive concept. The above descriptions made with reference to FIGS. 8A to 8D may be equally applied to FIGS. 9 to 13.

Referring to FIG. 9, compared to FIG. 8A, one first signal pad PD1 may include four insulating patterns PP1, PP2, PP3, and PP4, and there may be four alignment pads ALP1 to ALP4 at one end of the first pad region PA1.

A center of a first insulating pattern PP1 and a center of a first alignment pad ALP1 may have the same coordinate in the second direction DR2. A center of a second insulating pattern PP2 and a center of a second alignment pad ALP2 may have the same coordinate in the second direction DR2. A center of a third insulating pattern PP3 and a center of a third alignment pad ALP3 may have the same coordinate in the second direction DR2. A center of a fourth insulating pattern PP4 and a center of a fourth alignment pad ALP4 may have the same coordinate in the second direction DR2.

Since the center of the first alignment pad ALP1 is patterned to be at the same coordinate in the second direction DR2 as the center of the first insulating pattern PP1, the center of the first insulating pattern PP1 in the second direction DR2 may be determined from the center of the first alignment pad ALP1 in the second direction DR2. If the center of the first alignment pad ALP1 in the second direction DR2 does not have a coordinate in the second direction DR2 that falls within the range of coordinates in the second direction DR2 that is covered by the bump electrode BMP, the center of the first insulating pattern PP1 will also not have a coordinate value in the second direction DR2 that overlaps the range covered by the bump electrode BMP. Similarly, based on the position of the fourth alignment pad ALP4, the fourth insulating pattern PP4 will not overlap the bump electrode BMP in the second direction. In addition, seeing that the center of each of the second and third insulating patterns PP2 and PP3 falls within the range of coordinates in the second direction DR2 that is covered by the bump electrode BMP, the center of each of the second and third alignment pads ALP2 and ALP3 in the second direction DR2 will overlap the coordinates in the second direction DR2 covered by the bump electrode BMP in the second direction DR2. As a result, the bump electrode BMP may be positioned to overlap and bond to two insulating patterns PP2 and PP3 of the four insulating patterns PP1 to PP4.

The display panel DP (see FIG. 7) may further include a dummy alignment pad DM-ALP disposed in a first pad region PA1. The dummy alignment pad DM-ALP may include the same material as a dummy pad DMP. The dummy alignment pad DM-ALP may be formed in the same process as that for the dummy pad DMP. The dummy alignment pad DM-ALP may include a different material from materials of the alignment pad ALP and the insulating pattern PP. The dummy alignment pad DM-ALP may be formed in a different process from that for the alignment pad ALP and the insulating pattern PP.

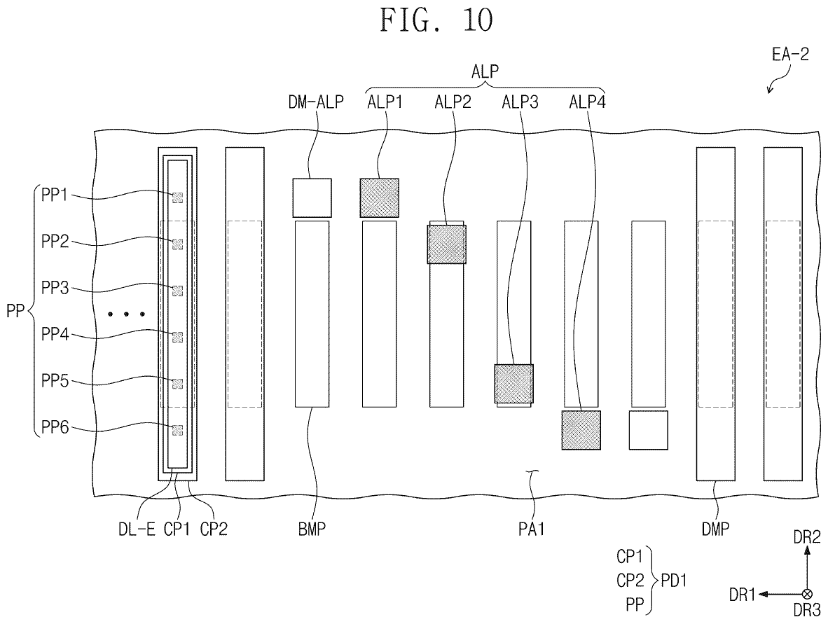

Referring to FIG. 10, compared to FIG. 8A, one first signal pad PD1 may include six insulating patterns PP1 to PP6 and four alignment pads ALP1 to ALP4 disposed in the first pad region PA1.

A center of a first insulating pattern PP1 in a second direction DR2 may have the same coordinate in the second direction DR2 as a center of a first alignment pad ALP1 in the second direction DR2. A center of a second insulating pattern PP2 in the second direction DR2 may have the same coordinate in the second direction DR2 as a center of a second alignment pad ALP2 in the second direction DR2. There may be no alignment pad ALP that shares the coordinates in the second direction DR2 with a center of each of a third insulating pattern PP3 and a fourth insulating pattern PP4 in the second direction DR2. A center of a fifth insulating pattern PP5 may have the same coordinates in the second direction DR2 as a center of a third alignment pad ALP3. A center of a sixth insulating pattern PP6 may have the same coordinates in the second direction DR2 as a center of a fourth alignment pad ALP4.

Since the center of the first alignment pad ALP1 in the second direction DR2 is patterned to be at the same coordinate in the second direction DR2 as the center of the first insulating pattern PP1, the center of the first insulating pattern PP1 in the second direction DR2 may be determined from the center of the first alignment pad ALP1. If the center of the first alignment pad ALP1 does not overlap the bump electrode BMP in the second direction DR2 (i.e., the coordinate for the center of the first alignment pad ALP1 in the second direction DR2 does not fall within the range of coordinates in the second direction DR2 covered by the bump electrode BMP), the center of the first insulating pattern PP1 in the second direction DR2 will also not have a coordinate value in the second direction DR2 that overlaps the range covered by the bump electrode BMP. Similarly, based on the position of the fourth alignment pad ALP4, that the sixth insulating pattern PP6 will not overlap the bump electrode BMP. In addition, seeing that the center of each of the second and third alignment pads ALP2 and ALP3 in the second direction DR2 overlaps the bump electrode BMP, the center of each of the second and fifth insulating patterns PP2 and PP5 in the second direction DR2 will overlap the coordinates covered by the bump electrode BMP. In addition, the centers of the third insulating pattern PP3 and fourth insulating pattern PP4 disposed between the second insulating pattern PP2 and the fifth insulating pattern PP5 may have coordinates in the second direction DR2 that fall within the range of coordinates in the second direction DR2 that is covered by the bump electrode BMP based on the fact that the center of each of the second and fifth insulating patterns PP2 and PP5 have coordinates in the second direction DR2 that overlap the coordinates of the bump electrode BMP. As a result, the bump electrode BMP may be positioned to overlap and bond to four insulating patterns PP2 to PP5 of the six insulating patterns PP1 to PP6.

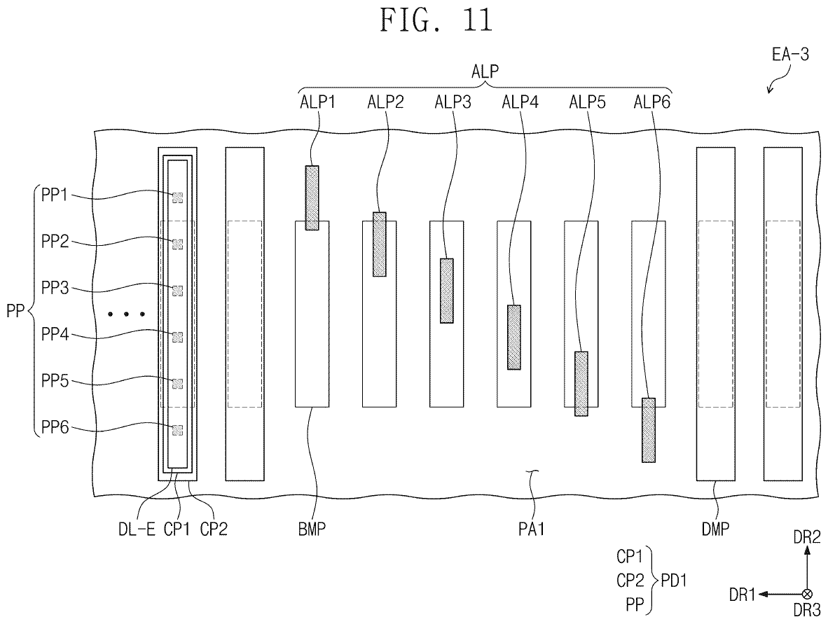

Referring to FIG. 11, compared to FIG. 8A, alignment pads ALP may have a rectangular shape in a plan view.

Centers of first to sixth alignment pads ALP1 to ALP6 having a rectangular shape and centers of first to sixth insulating patterns PP1 to PP6 may have the same coordinates in the second direction DR2, respectively.

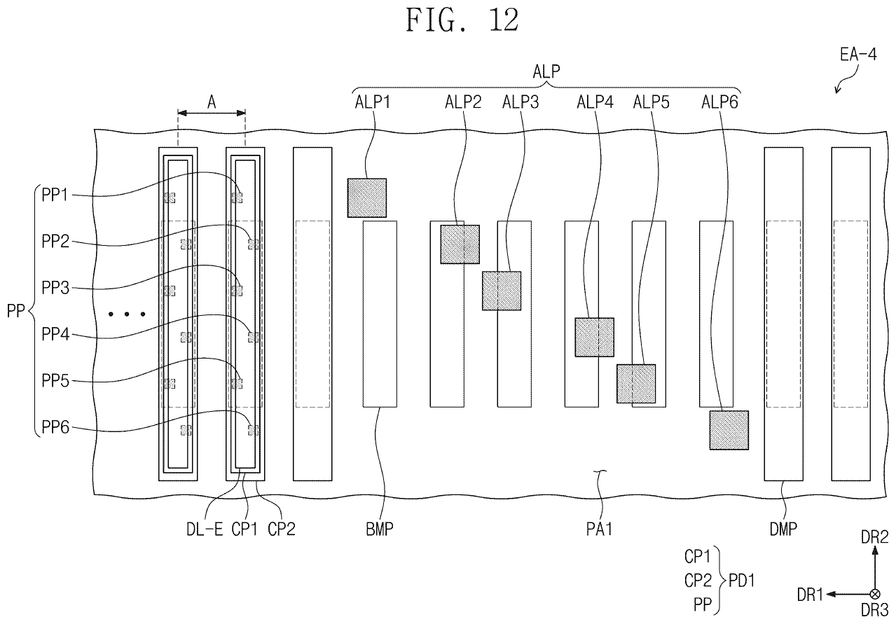

Referring to FIG. 12, compared to FIG. 8A, centers of first to sixth insulating patterns PP1 to PP6 may be offset from one another in the first direction DR1.

A distance between centers of first signal pads PD1 adjacent to each other in the first direction DR1 may be defined as distance A. FIG. 12 may be an example of a case in which one dummy pad DMP is disposed between first signal pads PD1 and alignment pads ALP. Here, a center of a first alignment pad ALP1 in the first direction DR1 may be spaced apart from a center of a first insulating pattern PP1 in the first direction DR1 by twice the distance A in the first direction DR1. A center of a second alignment pad ALP2 in the first direction DR1 may be disposed to be spaced apart from a center of a second insulating pattern PP2 in the first direction DR1 by three times the distance A in the first direction DR1. A center of a third alignment pad ALP3 in the first direction DR1 may be disposed to be spaced apart from a center of a third insulating pattern PP3 in the first direction DR1 by four times the distance A in the first direction DR1. A center of a fourth alignment pad ALP4 in the first direction DR1 may be disposed to be spaced apart from a center of a fourth insulating pattern PP4 in the first direction DR1 by five times the distance A in the first direction DR1. A center of a fifth alignment pad ALP5 in the first direction DR1 may be disposed to be spaced apart from a center of a fifth insulating pattern PP5 in the first direction DR1 by six times the distance A in the first direction DR1. A center of a sixth alignment pad ALP6 in the first direction DR1 may be disposed to be spaced apart from a center of a sixth insulating pattern PP6 in the first direction DR1 by seven times the distance A in the first direction DR1. Centers of the alignment pads ALP in the first direction DR1 may be overall changed by a constant distance according to the number of dummy pad DMP disposed between the first signal pads PD1 and the alignment pads ALP.

The description provided above with reference to FIG. 8A may be applied to centers of the alignment pads ALP1 to ALP6 in a second direction DR2 in the embodiment of FIG. 12. That is, centers of the first insulating pattern PP1 and the sixth insulating pattern PP6 have coordinates in the second direction DR2 that do not overlap the coordinates of the bump electrode BMP if the centers of the first alignment pad ALP1 and the sixth alignment pad ALP6 do not have coordinates in the second direction DR2 that overlap the coordinates of the bump electrode BMP. In addition, centers of the second to fifth insulating patterns PP2, PP3, PP4, and PP5 have coordinates in the second direction DR2 that overlap the range of coordinates covered by the bump electrode BMP if the centers of the second to fifth alignment pads ALP2, ALP3, ALP4, and ALP5 have coordinates in the second direction DR2 that overlap the range of coordinates covered by the bump electrode BMP.

A distance between a center of an alignment pad ALP and a center of a bump electrode BMP corresponding to the alignment pad ALP in the first direction DR1 may be the same as a distance between a center of an insulating pattern PP1 and a center of a bump electrode BMP corresponding to the insulating pattern PP1 in the first direction DR1. For example, a distance by which a center of the first alignment pad ALP1 in the first direction DR1 is spaced apart in the first direction DR1 from a center of a bump electrode BMP corresponding to the first alignment pad ALP1 in the first direction DR1 may be the same as a distance by which a center of the first insulating pattern PP1 is spaced apart in the first direction DR1 from a center of a bump electrode BMP corresponding to the first insulating pattern PP1.

Thus, centers of the second to fifth insulating patterns PP2 to PP5 have coordinates in the second direction DR2 that fall within the range of coordinates in the second direction DR2 covered by the bump electrode BMP if centers of the second to fifth alignment pads ALP2 to ALP5 have coordinates in the second direction DR2 that respectively fall within the range of coordinates in the second direction DR2 corresponding bump electrodes BMP. Hence, the alignment pads ALP may be used as a visual guide for positioning the bump electrode BMP relative to the insulation patterns PP.

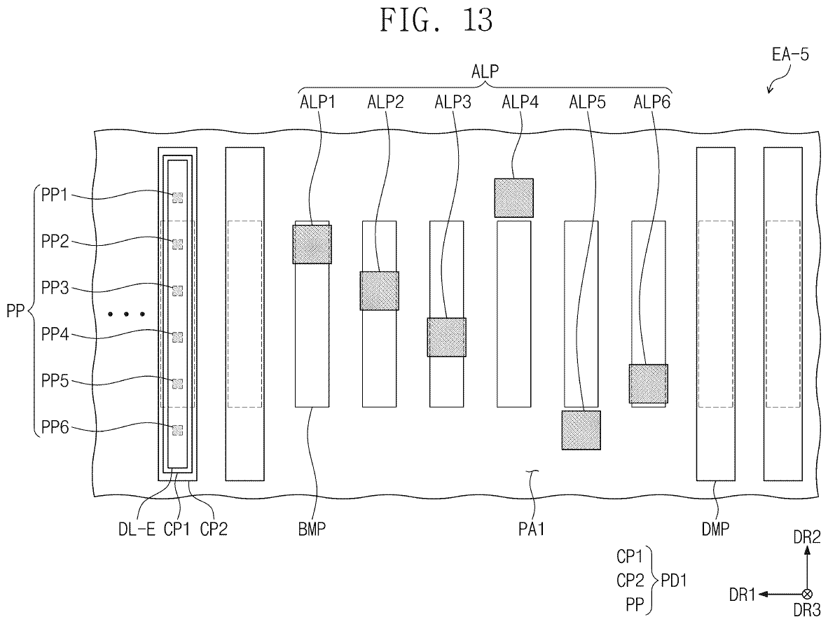

Referring to FIG. 13, the order in which insulating patterns PP are disposed in a second direction DR2 may not correlate linearly with the positions of the alignment pads ALP in the second direction DR2. A center of a first insulating pattern PP1 and a center of a fourth alignment pad ALP4 may have the same coordinate in the second direction DR2. A center of a second insulating pattern PP2 and a center of a first alignment pad ALP1 may have the same coordinate in the second direction DR2. A center of a third insulating pattern PP3 and a center of a second alignment pad ALP2 may have the same coordinate in the second direction DR2. A center of a fifth insulating pattern PP5 and a center of a sixth alignment pad ALP6 may have the same coordinate in the second direction DR2. A center of a sixth insulating pattern PP6 and a center of a fifth alignment pad ALP5 may have the same coordinate in the second direction DR2.

In an embodiment having such arrangement, the center of the second insulating pattern PP2 in the second direction DR2 may be determined from a position of the center of the first alignment pad ALP1 in the second direction DR2. The center of the third insulating pattern PP3 in the second direction DR2 may be determined from a position of the center of the second alignment pad ALP2 in the second direction DR2. The center of a fourth insulating pattern PP4 in the second direction DR2 may be determined from a position of a center of a third alignment pad ALP3 in the second direction DR2. The center of the first insulating pattern PP1 in the second direction DR2 may be determined from a position of the center of the fourth alignment pad ALP4 in the second direction DR2. The center of the sixth insulating pattern PP6 in the second direction DR2 may be determined from a position of the center of the fifth alignment pad ALP5 in the second direction DR2, and the center of the fifth insulating pattern PP5 in the second direction DR2 may be determined from a position of the center of the sixth alignment pad ALP6 in the second direction DR2.

Thus, the centers of the first and sixth insulating patterns PP1 and PP6 in the second direction DR2 do not have coordinates in the second direction DR2 that fall within the range of coordinates covered by a bump electrode BMP if the center of each of the fourth and fifth alignment pads ALP4 and ALP5 do not have coordinates in the second direction DR2 that fall within the coordinates of a corresponding bump electrode BMP. In addition, the second to fifth insulating patterns PP2, PP3, PP4, and PP5 can be determined to have coordinates in the second direction DR2 that fall within the coordinates of the bump electrode BMP from the fact that the centers of the first to third and sixth alignment pads ALP1, ALP2, ALP3, and ALP6 in the second direction DR2 respectively fall within the coordinates of the corresponding bump electrodes BMP. As a result, four insulating patterns PP2 to PP5 of the six insulating patterns PP1 to PP6 may be positioned to overlap and bond to the bump electrode BMP using the alignment pads for visual guidance.

According to the above descriptions, a display panel according to the inventive concept may include alignment pads spaced apart from polymer patterns of a pad by a constant distance, and thus it may be possible to precisely inspect positions of the polymer patterns.

In addition, an electronic apparatus according to the inventive concept may include the display panel including the alignment pads spaced apart from the polymer patterns of the pad by a constant distance, and thus it may be possible to inspect whether the polymer patterns of the pad and a bump of a data driver are aligned or not. Thus, bonding reliability between the display panel and the data driver may be improved.

Although description has been made with reference to embodiments of the inventive concept, it is understood that the inventive concept should not be limited to these embodiments, but various changes and modifications may be made by one ordinary skilled in the art within the spirit and scope of the inventive concept as hereinafter claimed. Therefore, the technical scope of the inventive concept is not limited to the contents described in the detailed description of the specification, but should be determined by the accompanying claims.

What is claimed is:

1. A display panel comprising:
a pixel;
a signal line electrically connected to the pixel;
a plurality of signal pads connected to the signal line; and
a plurality of alignment pads spaced apart from the plurality of signal pads in a first direction,
wherein the plurality of signal pads each include a first conductive pattern electrically connected to an end portion of the signal line, a second conductive pattern disposed on the first conductive pattern, and a plurality of insulating patterns disposed between the first conductive pattern and the second conductive pattern, and
the plurality of alignment pads and the plurality of insulating patterns include a same material.

2. The display panel of claim 1, wherein the plurality of insulating patterns are spaced apart from one another and arranged in a second direction perpendicular to the first direction, and
in a plan view, each of the plurality of insulating patterns is enclosed by the second conductive pattern and the first conductive pattern.

3. The display panel of claim 1, wherein a central point of at least one alignment pad among the plurality of alignment pads is at a same coordinate in the second direction as a central point of at least one insulating pattern among the plurality of insulating patterns.

4. The display panel of claim 1, wherein a distance in the first direction between a central point of at least one alignment pad among the plurality of alignment pads and a central point of at least one insulating pattern among the plurality of insulating patterns is an integer multiple of a distance in the first direction between central points of signal pads adjacent to each other among the plurality of signal pads.

5. The display panel of claim 1, wherein the plurality of alignment pads and the plurality of insulating patterns comprise a polymer.

6. The display panel of claim 1, wherein the plurality of alignment pads and the plurality of insulating patterns comprise a thermosetting polymer or a thermoplastic polymer.

7. The display panel of claim 1, wherein the plurality of alignment pads and the plurality of insulating patterns comprise a colored polymer, a translucent polymer, or an opaque polymer.

8. The display panel of claim 1, wherein the plurality of alignment pads and the plurality of insulating patterns are formed in a same process.

9. The display panel of claim 1, wherein in a plan view, each of the first conductive pattern and the second conductive pattern is distanced from the plurality of alignment pads.

10. The display panel of claim 1, wherein in a plan view, the plurality of alignment pads are disposed at an outer periphery of the plurality of signal pads.

11. The display panel of claim 1, further comprising a pad insulating layer disposed under the first conductive pattern,
wherein the plurality of alignment pads are disposed on the pad insulating layer.

12. The display panel of claim 1, further comprising at least one dummy pad disposed at an outer periphery of the plurality of signal pads in a plan view,
wherein the dummy pad includes a different material from materials of the alignment pad and the insulating pattern, and
the dummy pad is formed in a different process from that for the alignment pad and the insulating pattern.

13. The display panel of claim 1, wherein the plurality of insulating patterns comprise first to n-th insulating patterns arranged in a second direction perpendicular to the first direction,
central points of the respective first to n-th insulating patterns have the same coordinate in the second direction as a central point of at least one alignment pad among the plurality of alignment pads, and
n is an integer equal to or greater than 2.

14. The display panel of claim 1, wherein the plurality of alignment pads comprise first to n-th alignment pads, and
central points of the respective first to n-th alignment pads have the same coordinate in the second direction as a central point of at least one insulating pattern among the plurality of insulating patterns.

15. An electronic apparatus comprising:
a display panel including a plurality of signal pads and a plurality of alignment pads spaced apart from the plurality of signal pads in a first direction;
an electronic component including a plurality of bump electrodes, the electronic component electrically connected to the display panel through the plurality of bump electrodes; and
an adhesive layer bonding the display panel and the electronic component,
wherein the plurality of signal pads each include a first conductive pattern, a second conductive pattern disposed on the first conductive pattern, and a plurality of insulating patterns disposed between the first conductive pattern and the second conductive pattern, and
the plurality of alignment pads and the plurality of insulating patterns include a same material.

16. The electronic apparatus of claim 15, wherein in a plan view, at least one insulating pattern among the plurality of insulating patterns overlaps at least one bump electrode among the plurality of bump electrodes, and
in a plan view, at least one alignment pad among the plurality of alignment pads overlaps at least one bump electrode among the plurality of bump electrodes.

17. The electronic apparatus of claim 15, wherein the plurality of insulating patterns are spaced apart in a second direction perpendicular to the first direction, and
in a plan view, each of the plurality of insulating patterns is enclosed by the second conductive pattern and the first conductive pattern.

18. The electronic apparatus of claim 15, wherein a central point of at least one alignment pad among the plurality of alignment pads has the same coordinate in the second direction as a central point of at least one insulating pattern among the plurality of insulating patterns.

19. The electronic apparatus of claim 15, wherein a distance in the first direction between a central point of at least one alignment pad among the plurality of alignment pads and a central point of at least one insulating pattern among the plurality of insulating patterns is an integer multiple of a distance in the first direction between central points of bump electrodes adjacent to each other among the plurality of bump electrodes.

20. The electronic apparatus of claim 15, wherein the plurality of alignment pads and the plurality of insulating patterns each comprise a polymer, and
the plurality of alignment pads and the plurality of insulating patterns are formed in a same process.
